(19) United States
(12) Patent Application Publication
(10) Pub. No.: US 2026/0059734 A1
(43) Pub. Date: Feb. 26, 2026

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Jeong Hoon KWON, Gyeonggi-do (KR)

(21) Appl. No.: 19/078,278

(22) Filed: Mar. 13, 2025

(30) Foreign Application Priority Data
Aug. 23, 2024 (KR) 10-2024-0113367

(51) Int. Cl. H10B 12/00

(52) U.S. Cl. CPC H10B 12/30; H10B 12/03; H10B 12/05

(57) ABSTRACT

A semiconductor device may include high-integrated memory cells, and a method for fabricating the semiconductor device may include forming a mold stack including a plurality of mold layers that are vertically stacked over a substrate; forming a sacrificial layer in the mold stack; etching the sacrificial layer and forming a plurality of sacrificial layer patterns and a plurality of hole-shaped openings; forming pillar-shaped vertical dielectric layers filling the hole-shaped openings; removing the sacrificial layer patterns and forming damascene patterns self-aligned to the pillar-shaped vertical dielectric layers; and forming a vertical conductive line filling the damascene patterns.

### CROSS-REFERENCE TO RELATED APPLICATIONS

The present application claims priority under 35 U.S.C 119(a) to Korean Patent Application No. 10-2024-0113367, filed on Aug. 23, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the trend of large capacity and miniaturization of a memory device, a three-dimensional (3D) memory device in which a plurality of memory cells are stacked has been proposed.

### SUMMARY

Embodiments of the present disclosure provide a novel 3D semiconductor device with improved structure and performance characteristics and are directed to a semiconductor device including high-integrated memory cells, and a method for fabricating the semiconductor device.

In accordance with an embodiment of the present disclosure, a method for fabricating a semiconductor device may include forming a mold stack including a plurality of mold layers that are vertically stacked over a substrate; forming a sacrificial layer in the mold stack; etching the sacrificial layer and forming a plurality of sacrificial layer patterns and a plurality of hole-shaped openings; forming pillar-shaped vertical dielectric layers filling the hole-shaped openings; removing the sacrificial layer patterns and forming damascene patterns self-aligned to the pillar-shaped vertical dielectric layers; and forming a vertical conductive line filling the damascene patterns.

In accordance with an embodiment of the present disclosure, a method for fabricating a semiconductor device may include forming a column array and a row array of nano-sheets; forming a horizontal conductive line surrounding the nano-sheets with the row array; forming a sacrificial layer coupled to the nano-sheets with the column array and extending along the row array; etching the sacrificial layer and forming a plurality of sacrificial layer patterns and a plurality of hole-shaped openings that extend vertically along the column array and alternate with each other along the row array; forming pillar-shaped vertical dielectric layers filling the hole-shaped openings; removing the sacrificial layer patterns and forming damascene patterns exposing in common the nano-sheets with the column array and spaced apart from each other along the row array; and forming vertical conductive lines filling the damascene patterns, coupled in common the nano-sheets with the column array and spaced apart from each other along the row array.

In accordance with an embodiment of the present disclosure, a semiconductor device may include a column array and a row array of nano-sheets; horizontal conductive lines surrounding in common the nano-sheets with the row array and respectively surrounding the nano-sheets with the column array; data storage elements respectively coupled to the nano-sheets with the column array and the row array; a supporter including damascene patterns exposing in common the nano-sheets with the column array and respectively exposing the nano-sheets with the row array; and vertical conductive lines respectively filling the damascene patterns of the supporter, coupled in common to the nano-sheets with the column array, and respectively coupled to the nano-sheets with the row array.

In accordance with an embodiment of the present disclosure, a method for fabricating a semiconductor device may include forming a horizontal arrangement and a vertical arrangement of narrow-sheets; forming a horizontal conductive line surrounding the narrow-sheets of the horizontal arrangement; forming a sacrificial layer coupled to the narrow-sheets of the vertical arrangement and extending along the narrow-sheets of the horizontal arrangement; etching the sacrificial layer and forming a plurality of sacrificial layer patterns and a plurality of hole-shaped openings that extend vertically along the narrow-sheets of the vertical arrangement and alternate with each other along the narrow-sheets of the horizontal arrangement; forming pillar-shaped vertical dielectric layers filling the hole-shaped openings; removing the sacrificial layer patterns and forming damascene patterns exposing in common the narrow-sheets of the vertical arrangement and spaced apart from each other along the narrow-sheets of the horizontal arrangement; and forming vertical conductive lines filling the damascene patterns, coupled in common the narrow-sheets of the vertical arrangement and spaced apart from each other along the narrow-sheets of the horizontal arrangement.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2A is a schematic perspective view illustrating a semiconductor device in accordance with an embodiment of the present disclosure.

FIG. 2B is a schematic plan view illustrating a semiconductor device in accordance with an embodiment of the present disclosure.

FIG. 2C is a cross-sectional view of the semiconductor device taken along line A-A′ illustrated in FIG. 2B.

FIG. 2D is a cross-sectional view of the semiconductor device taken along line B-B′ illustrated in FIG. 2B.

FIG. 2E is a detailed plan view illustrating a supporter structure.

FIGS. 3A to 22B illustrate various views of a semiconductor device formed utilizing a method for fabricating the semiconductor device in accordance with an embodiment of the present disclosure.

FIGS. 23A and 23B are schematic cross-sectional views of a semiconductor device in accordance with an embodiment of the present disclosure.

FIGS. 24A and 24B illustrate various views illustrating a stack assembly in accordance with an embodiment of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiment relates to three-dimensional (3D) memory cells with memory cells vertically stacked for increasing the memory cell density and reducing parasitic capacitance.

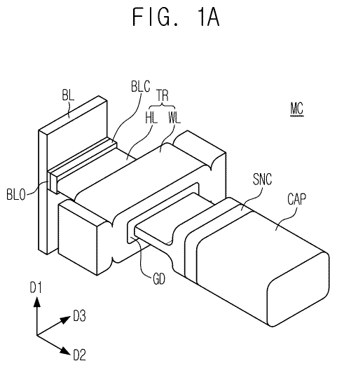

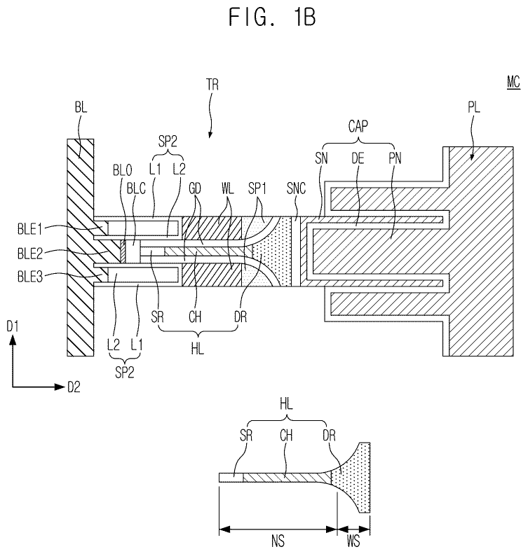

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten stack (TiN/W) in which titanium nitride and tungsten are sequentially stacked.

The switching element TR has a function of controlling voltage or current supply to the data storage element CAP during a data write operation and a data read operation performed onto the data storage element CAP. The switching element TR may include a nano-sheet HL, a nano-sheet dielectric layer GD, and a second conductive line WL. The second conductive line WL may include a horizontal conductive line or a horizontal word line, and the nano-sheet HL may include an active layer. The switching element TR may include a transistor, and in this case, the second conductive line WL may serve as a gate electrode. The switching element TR may also be referred to as a “nano-sheet transistor”, an “access element” or a “selection element”. The second conductive line WL may be referred to as a “horizontal gate electrode”or a “horizontal word line”.

The nano-sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano-sheet HL may extend in the first horizontal direction, i.e., the second direction D2, and the second conductive line WL may extend in the second horizontal direction, i.e., the third direction D3. The nano-sheet HL may be referred to as a “horizontal layer”.

The nano-sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. The height of the second doped region DR in the first direction D1 may be greater than the heights of the first doped region SR and the channel CH in the first direction D1. The length of the second doped region DR in the second direction D2 may be less than that of the channel CH in the second direction D2. The lengths of the first doped region SR, the channel CH and the second doped region DR in the third direction D3 may be equal to one another.

The nano-sheet HL may include a first region NS and a second region WS that are horizontally disposed in the second direction D2. The second region WS may extend from the first region NS. The second region WS may have a thickness that gradually increases in the second direction D2 from the first region NS toward the data storage element CAP between the first region NS and the data storage element CAP. An average vertical height or thickness of the second region WS in the first direction D1 may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS contacting the data storage element CAP and one side of the second doped region DR may each have a flat side shape.

A horizontal length of the wide sheet WS in the second direction D2 may be less than that of the narrow sheet NS. The narrow sheet NS may be referred to as a “long sheet”, and the wide sheet WS may be referred to as a “short sheet”.

The nano-sheet HL may include a semiconductive material. For example, the nano-sheet HL may include polysilicon, monocrystalline silicon, germanium, or silicon-germanium. In an embodiment, the nano-sheet HL may include an oxide semiconductor material. For example, the oxide semiconductor material may include indium gallium zinc oxide (IGZO), InSnZnO, ZnSnO, or a combination thereof. In an embodiment, the nano-sheet HL may include conductive metal oxide. In an embodiment, the nano-sheet HL may include a two-dimensional material, for example, MoS₂, WS₂, or MoSe_{2.}

When the nano-sheet HL is formed of the oxide semiconductor material, the channel CH may also be formed of the oxide semiconductor material, and the first and second doped regions SR and DR may be omitted. The nano-sheet HL may also be referred to as an “active layer”or a “thin body”.

The first doped region SR and the second doped region DR may be doped with the same conductivity type of impurities. The first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL, and the second doped region DR may be electrically coupled to the data storage element CAP. The first and second doped regions SR and DR may be referred to as “first and second source/drain regions”.

The nano-sheet HL may be horizontally oriented in the second direction D2 from the first conductive line BL.

The second conductive line WL may have a gate all around structure (GAA). For example, the second conductive line WL may surround the nano-sheet HL and extend in the third direction D3. A nano-sheet dielectric layer GD may be formed between the nano-sheet HL and the second conductive line WL. The nano-sheet dielectric layer GD may surround the nano-sheet HL.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of the low work function material and the high work function material.

The nano-sheet dielectric layer GD may be disposed between the nano-sheet HL and the second conductive line WL. The nano-sheet dielectric layer GD may be referred to as a “gate dielectric layer” or a “channel-side dielectric layer”. The nano-sheet dielectric layer GD may include silicon oxide, silicon nitride, metal oxide, metal oxide nitride, metal silicate, a high-k material, a ferroelectric material, an anti-ferroelectric material, or a combination thereof. The nano-sheet dielectric layer GD may include SiO₂, Si₃N₄, HfO₂, Al₂O₃, ZrO₂, AlON, HfON, HfSiO, HfSiON, HfZrO, or a combination thereof. The nano-sheet dielectric layer GD may be formed by thermal oxidation of the nano-sheet HL. The nano-sheet dielectric layer GD may be formed by a combination of deposition of silicon oxide and the thermal oxidation of the nano-sheet HL.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend from the nano-sheet HL in the second direction D2. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano-sheet HL. The second electrode PN of the data storage element CAP may be coupled to a common plate PL.

The data storage element CAP may have a three-dimensional structure. The first electrode SN may have a three-dimensional structure, and the first electrode SN having the three-dimensional structure may have the three-dimensional structure that is horizontally oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano-sheet HL. The dielectric layer DE and the second electrode PN may be disposed on the cylindrical inner surfaces and upper/lower outer surfaces of the first electrode SN.

In an embodiment, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In an embodiment, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In an embodiment, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In an embodiment, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In an embodiment, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

In an embodiment, the dielectric layer DE may include a ferroelectric material, an anti-ferroelectric material, or a combination thereof. For example, the dielectric layer DE may include HfZrO.

In an embodiment, the dielectric layer DE may include a combination of a high-k material and a ferroelectric material, a combination of a high-k material and an anti-ferroelectric material, or a combination of a high-k material or a ferroelectric material and an anti-ferroelectric material.

In an embodiment, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced by another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano-sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano-sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. The height of the first contact node BLC in the first direction D1 may be less than that of the second contact node SNC in the first direction D1. The height of the first contact node BLC in the first direction D1 may be greater than that of the channel CH in the first direction D1.

In an embodiment, the second contact node SNC may be selectively grown from the wide sheet WS of the nano-sheet HL. The second contact node SNC may be formed by selective epitaxial growth (SEG). For example, the second contact node SNC may be a silicon epitaxial layer formed by the selective epitaxial growth (SEG). The second contact node SNC may be a doped silicon epitaxial layer.

In an embodiment, the first contact node BLC may be selectively grown from the narrow sheet NS of the nano-sheet HL. The first contact node BLC may be formed by selective epitaxial growth (SEG). For example, the first contact node BLC may be a silicon epitaxial layer formed by the selective epitaxial growth (SEG). The first contact node BLC may be a doped silicon epitaxial layer.

The first contact node BLC may be a narrow sheet-side contact node, and the second contact node SNC may be a wide sheet-side contact node.

The nano-sheet HL may include a first edge and a second edge. The first edge may refer to a portion of the first doped region SR electrically coupled to the first conductive line BL, and the second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide. In an embodiment, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically coupled to one another. The second doped region DR, the second contact node SNC and the first electrode SN of the data storage element CAP may be electrically coupled to one another.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include, for example, silicon oxide, silicon nitride, or a combination thereof. The first spacer SP1 may include silicon nitride. The first liner L1 of the second spacer SP2 may be silicon nitride, and the second liner L2 may be silicon oxide. The first and second spacers SP1 and SP2 may be disposed on both sides of the second conductive line WL, respectively, and extend in the third direction D3 while surrounding the nano-sheet HL.

The first conductive line BL may include a plurality of horizontal extension portions BLE1, BLE2, and BLE3. The horizontal extension portions BLE1, BLE2, and BLE3 may extend in the second direction D2. The horizontal extension portions BLE1, BLE2, and BLE3 may include an inner horizontal extension portion BLE2 and outer horizontal extension portions BLE1 and BLE3. The inner horizontal extension portion BLE2 of the first conductive line BL may extend to be disposed in a gap of first liners L1 disposed vertically adjacent to each other. Accordingly, the inner horizontal extension portion BLE2 of the first conductive line BL may be electrically coupled to the ohmic contact layer BLO.

The outer horizontal portions BLE1 and BLE3 of the first conductive line BL may extend to be disposed in one side of the second spacer SP2. Accordingly, the outer horizontal portions BLE1 and BLE3 may contact the second liner L2 of the second spacer SP2.

In an embodiment, the horizontal extension portions BLE1, BLE2, and BLE3 of the first conductive line BL may be omitted.

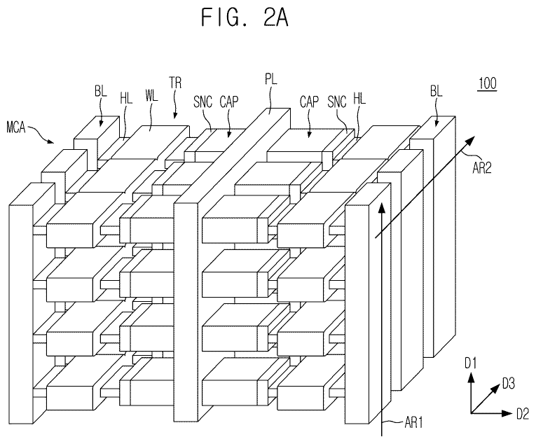

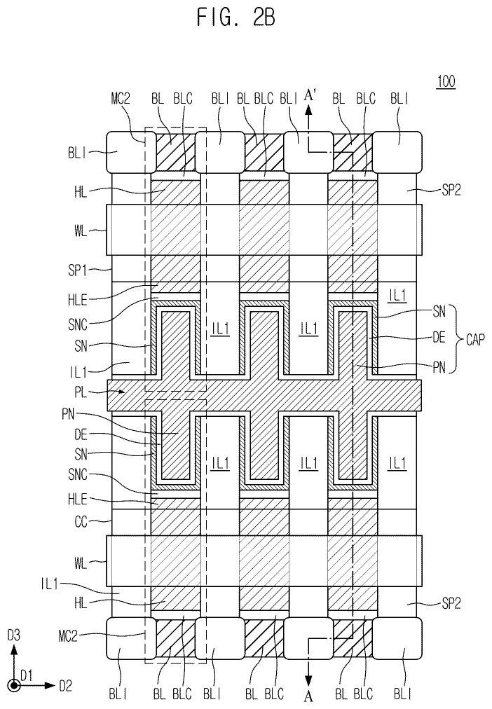

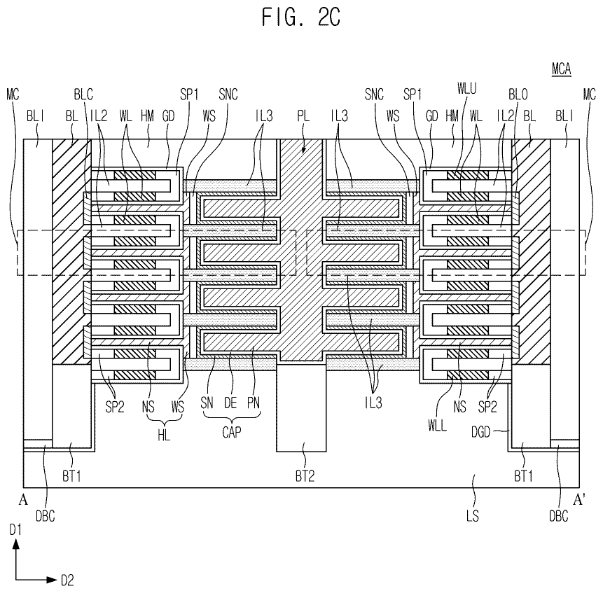

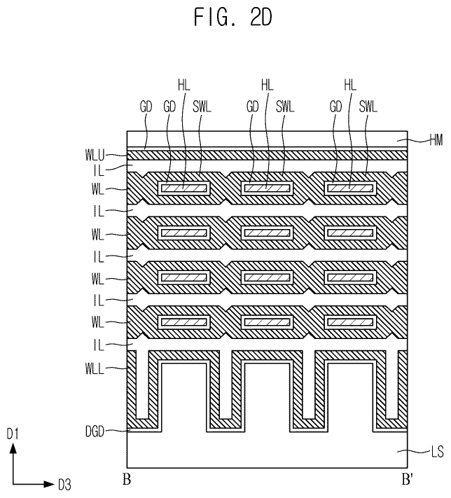

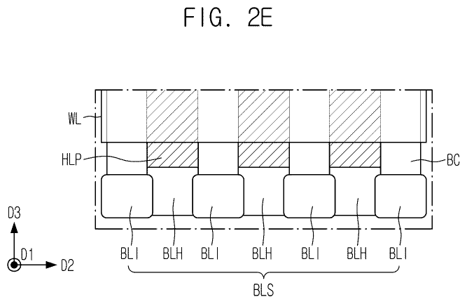

FIG. 2 is a schematic perspective view illustrating a semiconductor device 100 in accordance with an embodiment of the present disclosure. FIG. 2B is a schematic plan view illustrating the semiconductor device 100 in accordance with an embodiment of the present disclosure. FIG. 2C is a cross-sectional view of the semiconductor device 100 taken along line A-A′ illustrated in FIG. 2B. FIG. 2D is a cross-sectional view of the semiconductor device 100 taken along line B-B′ illustrated in FIG. 2B. FIG. 2E is a detailed plan view illustrating a supporter structure.

Referring to FIGS. 2A to 2D, the semiconductor device 100 may include a memory cell array MCA over a lower structure LS. The memory cell array MCA may include a three-dimensional array of memory cells MC. The memory cell array MCA may include a plurality of memory cells MC vertically stacked in a first direction D1. The memory cell array MCA may include a plurality of memory cells MC horizontally disposed in a second direction D2. The memory cell array MCA may include a plurality of memory cells MC horizontally disposed in a third direction D3. Each of the memory cells MC may be similar to the memory cell MC illustrated in FIGS. 1A and 1B.

Each of the memory cells MC may include a first conductive line BL, a switching element TR, and a data storage element CAP, and the switching element TR may include a second conductive line WL, a nano-sheet dielectric layer GD, and a nano-sheet HL. The nano-sheet HL may include a narrow sheet NS and a wide sheet WS. The nano-sheet HL may include a first doped region SR, a channel CH, and a second doped region DR, as described with reference to FIG. 1B. The first conductive line BL may include a plurality of horizontal extension portions (BLE1, BLE2 and BLE3 of FIG. 1B).

The memory cell array MCA may include a column array AR1 of the memory cells MC and a row array AR2 of the memory cells MC. The column array AR1 may include the plurality of memory cells MC vertically stacked in the first direction D1. The memory cells MC with the column array AR1 may share the first conductive line BL. The row array AR2 may include the plurality of memory cells MC horizontally disposed in the third direction D3. The memory cells MC with the row array AR2 may share the second conductive line WL. The first direction D1 may be a vertical direction, and the third direction D3 may be a horizontal direction. The second conductive line WL may surround the nano-sheets HL at the same horizontal level. Referring to FIG. 2D, the second conductive line WL may include surrounding electrodes SWL surrounding the nano-sheets HL, and the surrounding electrodes SWL may be merged with one another.

First inter-cell dielectric layers IL1 may be disposed between the data storage elements CAP disposed adjacent to each other in the third direction D3. Second inter-cell dielectric layers IL2 may be disposed between the second conductive lines WL stacked in the first direction D1. Third inter-cell dielectric layers IL3 may be disposed between first electrodes SN of the data storage elements CAP stacked in the first direction D1. The first to third inter-cell dielectric layers IL1, IL2 and IL3 may each include, for example, silicon oxide, silicon carbon oxide (SiCO), silicon nitride, an air gap, air gap-embedded oxide, or a combination thereof. The first inter-cell dielectric layers IL1 may be referred to as “device isolation layers”.

Each of the memory cells MC may further include a first contact node BLC and a second contact node SNC. The first contact node BLC may be disposed between the first conductive line BL and the nano-sheet HL. The first contact node BLC may include a metal-based material or a semiconductive material. For example, the first contact node BLC may include doped polysilicon, titanium, titanium nitride, tungsten, or a combination thereof. The second contact node SNC may be disposed between the nano-sheet HL and the first electrode SN. The second contact node SNC may include a metal-based material or a semiconductive material. For example, the second contact node SNC may include doped polysilicon, titanium, titanium nitride, tungsten, or a combination thereof. The height of the first contact node BLC in the first direction D1 may be less than that of the second contact node SNC in the first direction D1. The height of the first contact node BLC in the first direction D1 may be greater than that of the channel CH in the first direction D1.

The first contact node BLC may be selectively grown from the nano-sheet HL. The first contact node BLC may be formed by selective epitaxial growth (SEG). For example, the first contact node BLC may be a silicon epitaxial layer formed by the selective epitaxial growth (SEG). The first contact node BLC may be a doped silicon epitaxial layer.

The second contact node SNC may be selectively grown from the nano-sheet HL. The second contact node SNC may be formed by the selective epitaxial growth (SEG). For example, the second contact node SNC may be a silicon epitaxial layer formed by the selective epitaxial growth (SEG). The second contact node SNC may be a doped silicon epitaxial layer.

The memory cells MC may further include an ohmic contact layer BLO disposed between the first contact node BLC and the first conductive line BL, as described with reference to FIGS. 1A and 1B. The ohmic contact layer BLO may include metal silicide.

Each of the memory cells MC may further include a first spacer SP1 and a second spacer SP2. The first spacer SP1 may be disposed between the second conductive line WL and the wide sheet WS of the nano-sheet HL. The second spacer SP2 may be disposed between the first conductive line BL and the second conductive line WL. The first and second spacers SP1 and SP2 may each include a dielectric material. The first and second spacers SP1 and SP2 may each include, for example, silicon oxide, silicon nitride, or a combination thereof. The first spacer SP1 may cover one side of each of the second inter-cell dielectric layers IL2. The first spacer SP1 may have a cup shape, for example, a ⊃ shape. In an embodiment, the second spacer SP2 may include a stack of a first liner L1 and a second liner L2, as described with reference to FIG. 1B.

The memory cell array MCA may include a plurality of second conductive lines WL vertically stacked in the first direction D1. The memory cell array MCA may include a plurality of nano-sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may include dummy second conductive lines WLU and WLL disposed at a level higher than an uppermost second conductive line WL and at a level lower than a lowermost second conductive line WL, respectively. The dummy second conductive lines WLU and WLL may each have a linear shape extending horizontally.

A first bottom protection layer BT1 may be formed below the first conductive line BL, and a second bottom protection layer BT2 may be formed below a common plate PL and a dielectric layer DE. The first and second bottom protection layers BT1 and BT2 may each include, for example, silicon oxide, silicon nitride, silicon carbon oxide, or a combination thereof.

Dummy structures DBC and DGD may be disposed on the periphery of the first and second bottom protection layers BT1 and BT2. The dummy structures may include a dummy spacer DBC and a dummy nano-sheet dielectric layer DGD.

A hard mask layer HM may be disposed over the uppermost second conductive line WL. The hard mask layer HM may include a multi-level hard mask material.

The nano-sheets HL of the switching elements TR horizontally disposed in the third direction D3 may share one second conductive line WL. The nano-sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to the common plate PL.

The lower structure LS may be disposed at a lower level than the memory cell array MCA. The lower structure LS may be a material suitable for semiconductor processing. The lower structure LS may include at least one of a conductive material, a dielectric material and a semiconductive material. Various materials may be formed over the lower structure LS. The lower structure LS may include a semiconductor substrate. The lower structure LS may be formed of a silicon-containing material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The lower structure LS may include another semiconductor material, such as germanium. The lower structure LS may include a III/V-group semiconductor substrate, for example, a chemical compound semiconductor substrate such as gallium arsenide (GaAs). The lower structure LS may include a Silicon-On-Insulator (SOI) substrate. The lower structure LS may be referred to as a “base body”.

In an embodiment, the lower structure LS may include a metal wiring structure, a dielectric structure, a conductive structure, a bonding pad structure, another memory, or a peripheral circuit portion. For example, the lower structure LS may include a structure in which the peripheral circuit portion, the metal wiring structure and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof. The peripheral circuit portion of the lower structure LS may be disposed at a lower level than the memory cell array MCA. This may be referred to as a “PERI under cell (PUC) structure”or a “cell array over PERI (COP) structure”.

The peripheral circuit portion of the lower structure LS may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The second conductive lines WL may be coupled to the sub-word line drivers. The first conductive line BL may be coupled to the sense amplifier.

In an embodiment, the lower structure LS may include a semiconductor substrate, and the memory cell array MCA may be disposed over the lower structure LS, and the peripheral circuit portion may be disposed over the memory cell array MCA. This may be referred to as a “PERI over cell (POC) structure” or a “cell under PERI (CUP) structure”.

In an embodiment, the memory cell array MCA may include DRAM, embedded DRAM, NAND, FeRAM, STTRAM, PCRAM, or ReRAM.

Referring back to FIGS. 2B and 2E, the first conductive lines BL may be supported by a supporter structure BLS. The supporter structure BLS may include a plurality of damascene patterns BLH and a plurality of supporters BLI. Each of the first conductive lines BL may fill a different one of the damascene patterns BLH. The supporters BLI may be formed between the first conductive lines BL disposed adjacent to each other in the third direction D3. The supporters BLI may include a material for isolation between the first conductive lines BL, for example, a dielectric material. The first conductive lines BL may be self-aligned to the supporters BLI and formed in the damascene patterns BLH. The damascene patterns BLH may each have a hole shape.

As described above according to embodiments, the semiconductor device 100 may include column and row arrays of the nano-sheets HL, the horizontally-oriented second conductive lines WL that surround in common the nano-sheets HL with the row array and surround the respective nano-sheets HL with the column array, the data storage elements CAP coupled to the respective nano-sheets HL with the column and row arrays, the supporter BLI that exposes in common the nano-sheets HL with the row array and includes damascene patterns exposing the nano-sheets HL with the row array, and the vertically-oriented first conductive lines BL that fill the respective damascene patterns of the supporter BLI, are coupled in common to the nano-sheets HL with the column array and are coupled to the respective nano-sheets HL with the row array.

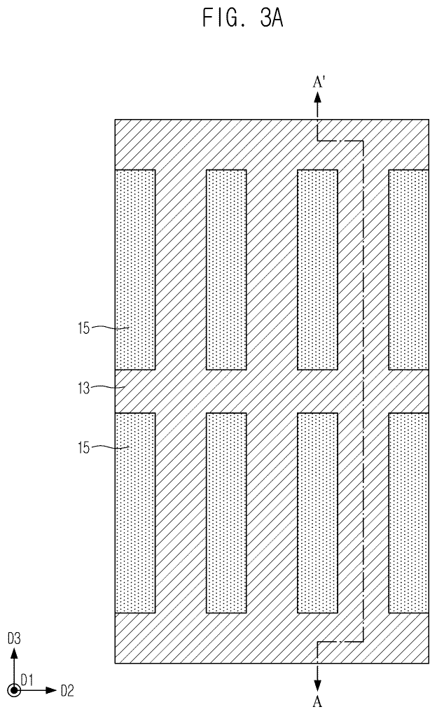

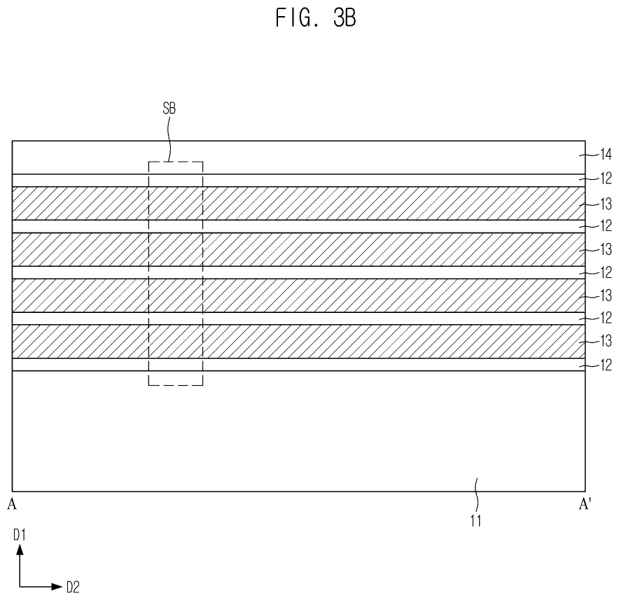

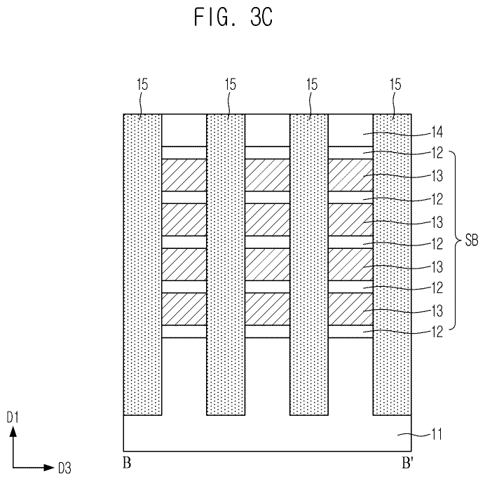

FIGS. 3A to 22B illustrate various views of a semiconductor device formed utilizing a method for fabricating the semiconductor device in accordance with an embodiment of the present disclosure.

FIG. 3A is a plan view illustrating a structure at a second mold layer level for describing a method for forming sacrificial isolation layers 15, and FIG. 3B is a cross-sectional view of the structure taken along line A-A′ illustrated in FIG. 3A, and FIG. 3C is a cross-sectional view of the structure taken along line B-B′ illustrated in FIG. 3A.

As illustrated in FIGS. 3A to 3C, a mold stack SB may be formed on a substrate 11.

The substrate 11 may be a material suitable for semiconductor processing. The substrate 11 may include a semiconductive material. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The substrate 11 may include another semiconductor material, such as germanium. The substrate 11 may include a III/V-group semiconductor substrate, for example, a chemical compound semiconductor substrate such as gallium arsenide (GaAs). The substrate 11 may include a Silicon-On-Insulator (SOI) substrate. The substrate 11 may be referred to as a “base body”.

The mold stack SB may include an alternating stack of first mold layers 12 and second mold layers 13.

The first mold layers 12 may be alternately stacked with the second mold layers 13, and the first mold layers 12 and the second mold layers 13 may be epitaxially grown multiple times, to form the mold stack SB. The first mold layers 12 and the second mold layers 13 may be epitaxially grown on the substrate 11.

The first mold layers 12 and the second mold layers 13 may be different semiconductive materials. The first mold layers 12 may include silicon germanium or monocrystalline silicon germanium. The second mold layers 13 may include monocrystalline silicon. The first mold layers 12 and the second mold layers 13 may be formed by an epitaxial growth process. A lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano-sheet target layers”or “recess target layers”.

The mold stack SB may be referred to as a “vertical stack”. A plurality of sacrificial layers 12 may be alternately stacked with a plurality of nano-sheet target layers 13, to form the mold stack SB. The sacrificial layers 12 may be monocrystalline silicon germanium layers. The nano-sheet target layers 13 may be monocrystalline silicon layers.

A thickness ratio of the first mold layers 12 and the second mold layers 13 in the mold stack SB may be variously modified. The thickness of the first mold layers 12 may be less than the thickness of the second mold layers 13. For example, the thickness of each of the first mold layers 12 may be approximately 5 to 20 nm. The thickness of each of the second mold layers 13 may be approximately 50 to 80 nm. The number of alternations of the first and second mold layers 12 and 13 in the mold stack SB may be variously modified. In an embodiment, a triple stack including the first mold layer 12 then the second mold layer 13 over the first mold stack 12, and then another first mold layer 12 over the second mold stack 13 may be defined at lowermost and/or uppermost portions of the mold stack SB. This stack may be simply referred to as a triple stack.

A first hard mask layer 14 may be formed on the mold stack SB. The first hard mask layer 14 may include a dielectric material. The dielectric material may be, for example, an oxide-based material, a nitride-based material, a carbon-based material, or a combination thereof. In an embodiment, the first hard mask layer 14 may include silicon dioxide (SiO₂), silicon nitride (Si₃N₄) amorphous carbon, or a combination thereof.

Subsequently, following the formation of the hard mask layer 14, a plurality of sacrificial isolation layers 15 may be formed in the mold stack SB. Forming the sacrificial isolation layers 15 may include forming a plurality of sacrificial isolation openings by etching portions of the mold stack SB using the first hard mask layer 14 as a barrier and forming sacrificial isolation materials that fill the sacrificial isolation openings. The sacrificial isolation openings may be initial openings for cell isolation. From the perspective of a top view, cross-sections of the sacrificial isolation openings may each have a rectangular shape. However, the embodiment may not be limited by the shape of the cross-section of the sacrificial isolation openings. For example, in an embodiment, the cross-sections of the sacrificial isolation openings may each have a circular-shape. In another embodiment, the cross-sections of the sacrificial isolation openings may each have an oval-shape. In an embodiment, the sacrificial isolation openings may be referred to as “sacrificial isolation trenches”. The sacrificial isolation openings may extend vertically in a first direction D1, and also lengthwise in a second direction D2. The plurality of the sacrificial isolation openings may be spaced apart at a predetermined interval along a third direction D3. The sacrificial isolation openings may extend inside the substrate 11.

The sacrificial isolation layers 15 may fill the sacrificial isolation openings. The sacrificial isolation layers 15 may include the same material. The sacrificial isolation layers 15 may be formed of a dielectric material. The sacrificial isolation layers 15 may have an etch selectivity with respect to the mold stack SB. For example, the sacrificial isolation layers 15 may each include, for example, silicon oxide, silicon nitride, silicon carbon oxide, silicon carbon nitride, or a combination thereof. Forming the sacrificial isolation layers 15 may include forming sacrificial isolation materials on the first hard mask layer 14 to fill the sacrificial isolation openings and planarizing the sacrificial isolation materials so that a surface of the first hard mask layer 14 is exposed.

Referring to FIG. 3C, The sacrificial isolation layers 15 may extend vertically in the first direction D1 and extend lengthwise in the second direction D2. The sacrificial isolation layers 15 may be disposed at a predetermined interval in the third direction D3. Each of the sacrificial isolation layers 15 may include a stack of a first sacrificial liner layer and a first sacrificial gap-fill layer. The first sacrificial liner layer may be silicon nitride, and the first sacrificial gap-fill layer may be silicon oxide. The sacrificial isolation layers 15 may penetrate the mold stack SB in the first direction D1.

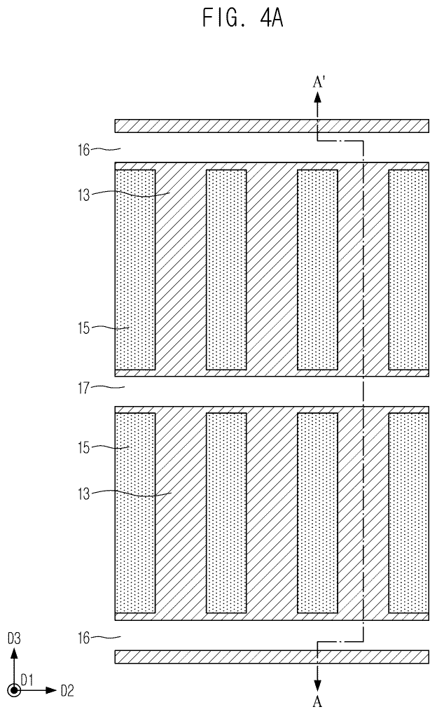

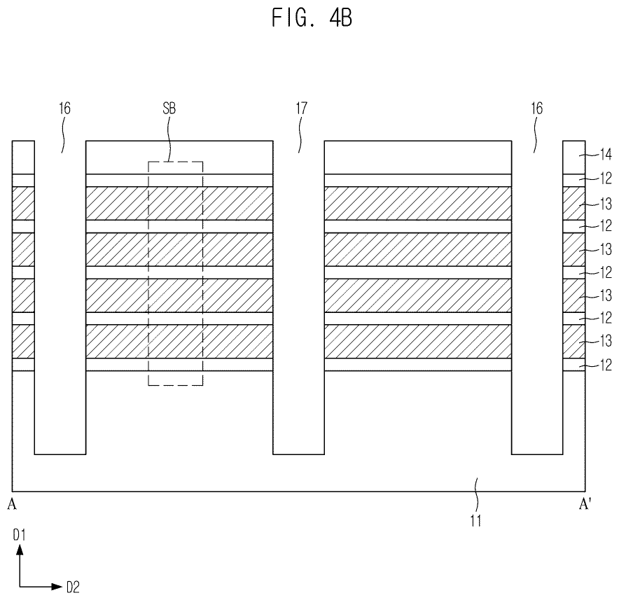

FIG. 4A is a plan view illustrating the structure at the second mold layer level for describing a method for forming sacrificial linear openings 16 and 17. FIG. 4B is a cross-sectional view of the structure taken along line B-B′ illustrated in FIG. 4A.

As illustrated in FIGS. 4A and 4B, the first hard mask layer 14 may be etched first, and then portions of the mold stack SB may be etched. Accordingly, a plurality of sacrificial linear openings 16 and 17 may be formed between the sacrificial isolation layers 15. The sacrificial linear openings 16 and 17 may include a first sacrificial linear opening 16 and a second sacrificial linear opening 17. From the perspective of a top view, the first sacrificial linear opening 16 and the second sacrificial linear opening 17 may be line-shaped openings extending in the third direction D3. The first sacrificial linear opening 16 and the second sacrificial linear opening 17 may extend vertically in the first direction D1. The sacrificial isolation layers 15 may be disposed between the first sacrificial linear opening 16 and the second sacrificial linear opening 17 in the second direction D2. From the perspective of a top view, cross sections of the first and second sacrificial linear openings 16 and 17 may each have a rectangular shape. However, the embodiment may not be limited by the shape of the first and second sacrificial openings 16 and 17. For example, in an embodiment, the cross sections of the first and second sacrificial linear openings 16 and 17 may each have a circular-shape. In another embodiment, the cross sections of the first and second sacrificial linear openings 16 and 17 may each have an oval-shape. The first and second sacrificial linear openings 16 and 17 may each have a width in the second direction D2 less than a width in the third direction D3. The first and second sacrificial linear openings 16 and 17 may be referred to as “sacrificial linear trenches”. The sacrificial isolation layers 15 may not contact the first and second sacrificial linear openings 16 and 17.

Bottom surfaces of the first and second sacrificial linear openings 16 and 17 may extend inside the substrate 11.

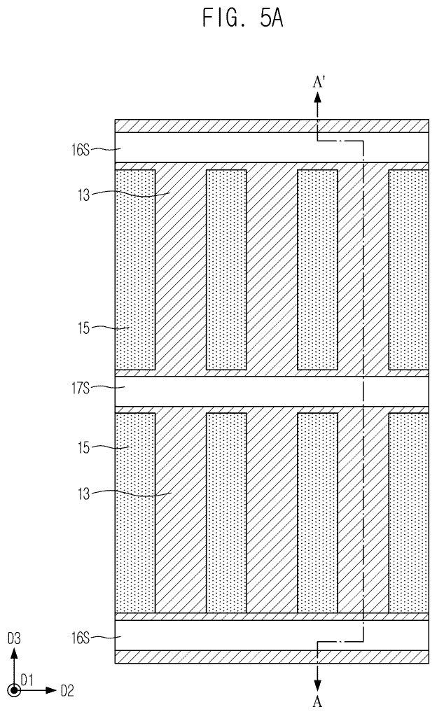

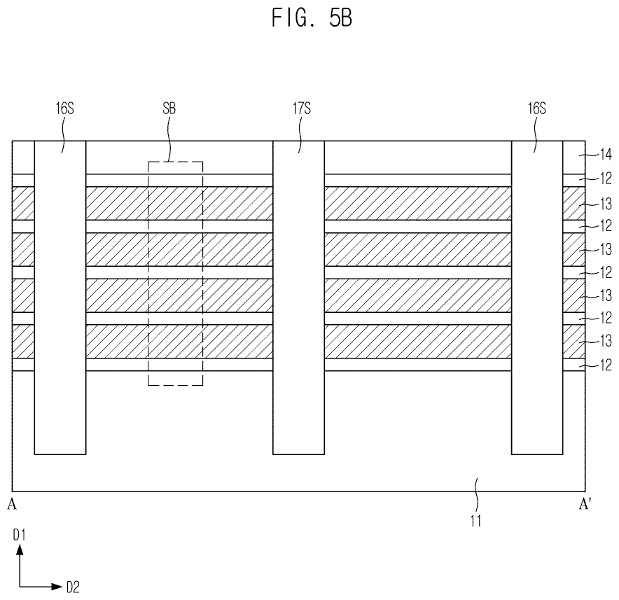

FIG. 5A is a plan view illustrating the structure at the second mold layer level for describing a method for forming linear sacrificial layers 16S and 17S. FIG. 5B is a cross-sectional view of the structure taken along line A-A′ illustrated in FIG. 5A.

As illustrated in FIGS. 5A and 5B, the linear sacrificial layers 16S and 17S may be formed to fill the first and second sacrificial linear openings 16 and 17. The linear sacrificial layers 16S and 17S may include a first linear sacrificial layer 16S and a second linear sacrificial layer 17S. From the perspective of a top view the first linear sacrificial layer 16S and the second linear sacrificial layer 17S may have line shapes extending in the third direction D3. The first linear sacrificial layer 16S and the second linear sacrificial layer 17S may extend vertically in the first direction D1. (See FIG. 5B). The sacrificial isolation layers 15 may be disposed between the first linear sacrificial layer 16S and the second linear sacrificial layer 17 in the second direction D2. From the perspective of a top view, cross sections of the first and second linear sacrificial layers 16S and 17S may each have a rectangular shape. However, the embodiment may not be limited by the shape of the cross-sections of the first and second sacrificial layers 16S and 17S. In an embodiment, the cross-sections of the first and second linear sacrificial layers 16S and 17S may each have a circular-shape In another embodiment, the cross-sections of the first and second linear sacrificial layers 16S and 17S may each have an oval-shape. The first and second linear sacrificial layers 16S and 17S may include the same material. The first and second linear sacrificial layers 16S and 17S may be formed of a dielectric material. For example, the first and second linear sacrificial layers 16S and 17S may each include, for example, silicon oxide, silicon nitride, silicon carbon oxide, silicon carbon nitride, or a combination thereof. The sacrificial isolation layers 15 may not contact the first and second linear sacrificial layers 16S and 17S.

Bottom surfaces of the first and second linear sacrificial layers 16S and 17S may contact the substrate 11.

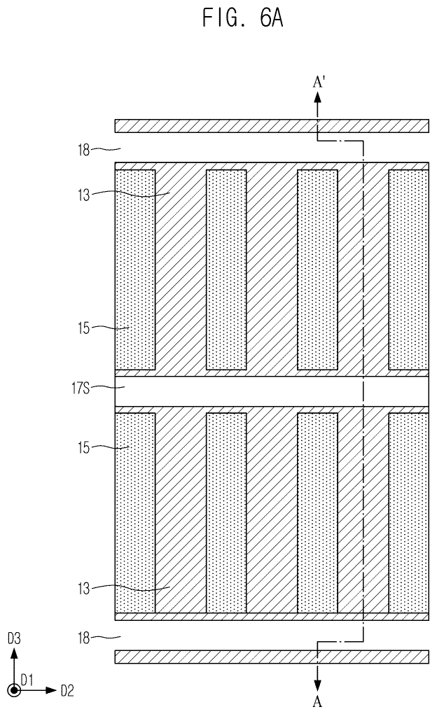

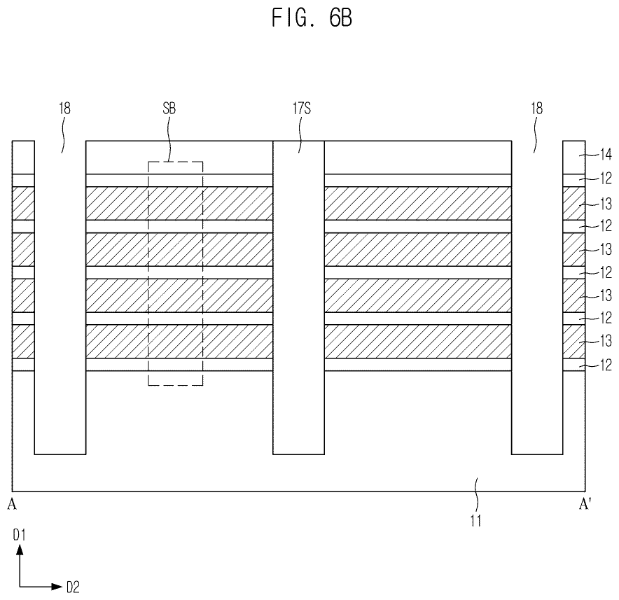

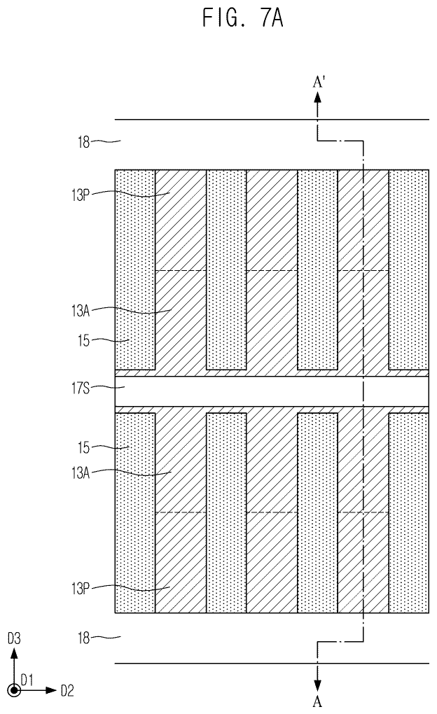

FIG. 6A is a plan view illustrating the structure at the second mold layer level for describing a method for forming first linear openings 18. FIG. 6B is a cross-sectional view of the structure taken along line A-A′ illustrated in FIG. 6A.

As illustrated in FIGS. 6A and 6B, among the first linear sacrificial layer 16S and the second linear sacrificial layer 17S, the first linear sacrificial layer 16S may be selectively removed and the first linear opening 18 may be formed. From the perspective of a top view, the first linear openings 18 may be disposed horizontally spaced apart from the second linear sacrificial layer 17S in the second direction D2.

A bottom surface of the first linear opening 18 may be at the same level as a bottom surface of the second linear sacrificial layer 17S. (Please see FIG. 6B). The bottom surface of the first linear opening 18 may be at the same level as bottom surfaces of the sacrificial isolation layers 15.

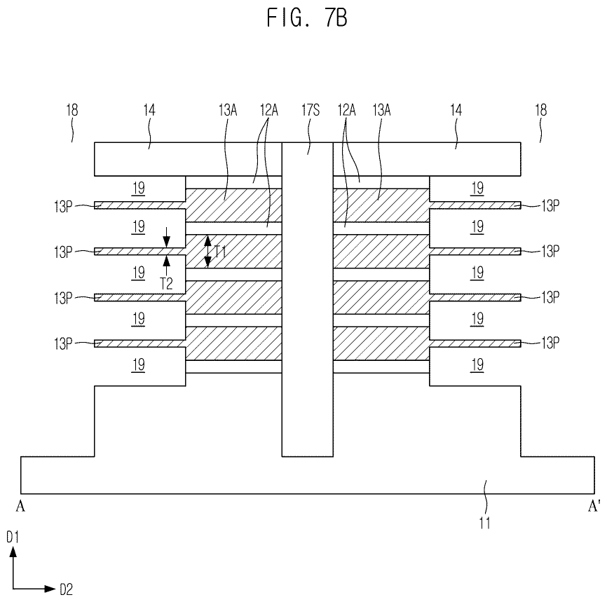

FIG. 7A is a plan view illustrating the structure at the second mold layer level for describing a method for partially recessing the first and second mold layers 12 and 13. FIG. 7B is a cross-sectional view of the structure taken along line A-A′ illustrated in FIG. 7A.

As illustrated in FIGS. 7A and 7B, the first mold layers 12 may be selectively recessed through the first linear openings 18. To selectively recess the first mold layers 12, a difference in etch selectivity between the first mold layers 12 and the second mold layers 13 may be used. The first mold layers 12 may be removed using a wet etch process or a dry etch process. For example, when the first mold layers 12 include silicon germanium layers and the second mold layers 13 include monocrystalline silicon layers, the silicon germanium layers may be etched using an etchant or etch gas having a selectivity with respect to the monocrystalline silicon layers. The first mold layers having an original thickness may remain as indicated by reference numeral “12A”.

Subsequently, portions (first portions) of the second mold layers 13 may be recessed to form narrow sheets 13P. Wet or dry etching may be used for recessing the second mold layers 13. Original body portions 13A and the narrow sheets 13P may be formed by the partial recessing of the second mold layers 13. The original body portions 13A may each maintain an original thickness T1, and the narrow sheets 13P may each have a thickness T2 less than the original thickness T1. Horizontal lengths of the original body portions 13A in the second direction D2 may be equal to or different from horizontal lengths of the narrow sheets 13P in the second direction D2. A combination of each original body portion 13A and each narrow sheet 13P may be referred to as a “preliminary nano-sheet layer”. The narrow sheets 13P may be referred to as “flat plate-shaped sheets”or “protruding narrow sheets”.

A recess process for forming the narrow sheets 13P may be referred to as a “thinning process” or “trimming process” of the second mold layers 13. To form the narrow sheets 13P, upper surfaces, lower surfaces and side surfaces of the second mold layers 13 may be recessed. The narrow sheets 13P may each include a monocrystalline silicon layer. The recess process for forming the narrow sheets 13P may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13P may be formed by the partial recess process for the second mold layers 13 as described above, and inter-nano-sheet recesses 19 may be formed between the narrow sheets 13P that are vertically disposed. Upper and lower surfaces of the narrow sheets 13P may each include a flat surface. A boundary portion between each original body portion 13A and each narrow sheet 13P may be vertical or have a curvature. The first mold layers 12A may be disposed between the original body portions 13A that are vertically stacked. According to FIGS. 7A and 7B, horizontal and vertical arrangements of narrow sheets 13P may be formed. The horizontal arrangement of narrow sheets 13P may be formed such that the narrow sheets 13P are disposed horizontally along the third direction D3, and the vertical arrangement of narrow sheets 13P may be formed such that the narrow sheets 13P are disposed vertically along the first direction D1.

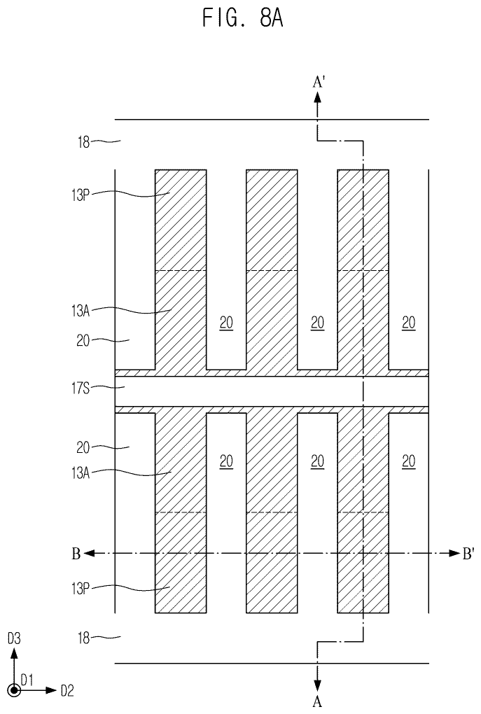

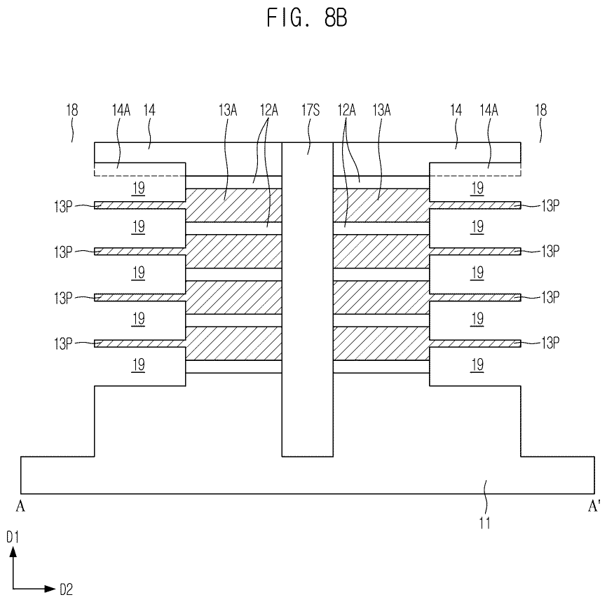

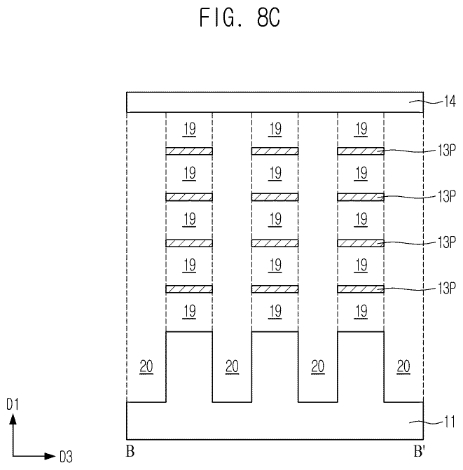

FIG. 8A is a plan view illustrating the structure at a narrow sheet level for describing a method for forming sacrificial isolation layer-level openings 20. FIG. 8B is a cross-sectional view of the structure taken along line A-A′ illustrated in FIG. 8A. FIG. 8C is a cross-sectional view of the structure taken along line B-B′ illustrated in FIG. 8A.

As illustrated in FIGS. 8A to 8C, the sacrificial isolation layers 15 may be selectively stripped through the inter-nano-sheet recesses 19 and the first linear openings 18. Accordingly, the sacrificial isolation layer-level openings 20 may be formed between the original body portions 13A in the third direction D3.

Side surfaces of the first mold layers 12A, side surfaces of the original body portions 13A, and side surfaces of the narrow sheets 13P may be exposed in the third direction D3 by the sacrificial isolation layer-level openings 20.

In an embodiment, while the sacrificial isolation layer-level openings 20 are formed, a portion of the first hard mask layer 14 may be recessed. Accordingly, a space of an uppermost inter-nano-sheet recess 19 may be expanded. The inter-nano-sheet recesses 19 may have the same size.

The inter-nano-sheet recesses 19 and the sacrificial isolation layer-level openings 20 may be continuous to each other.

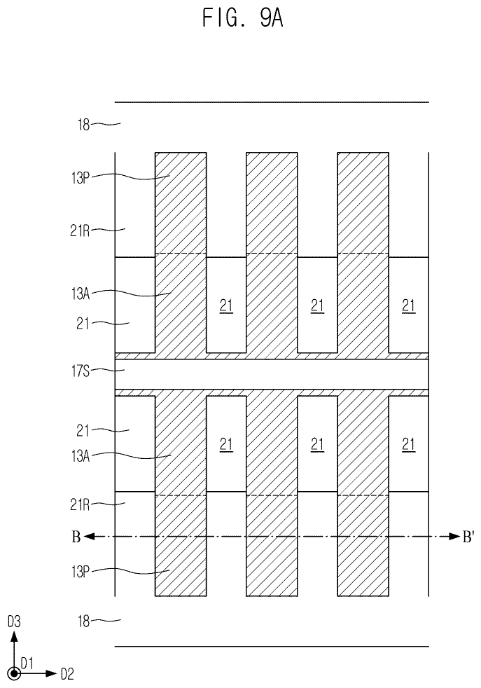

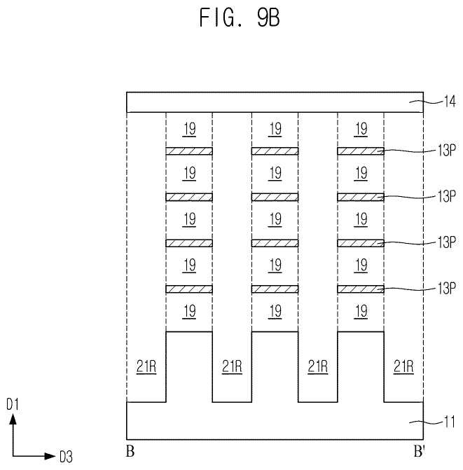

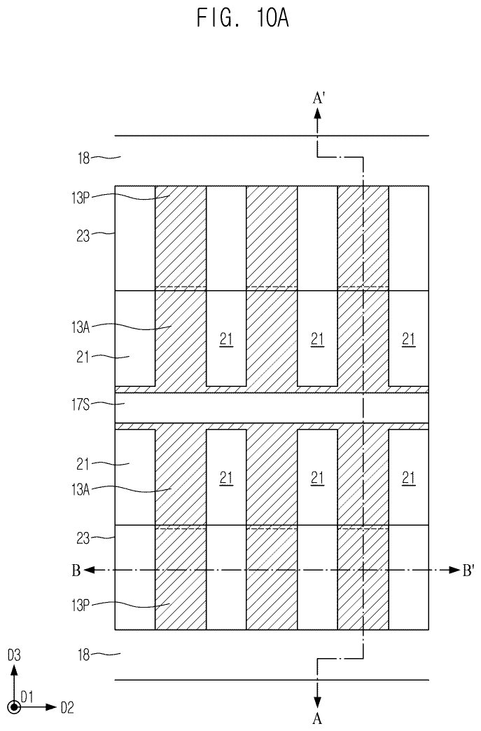

FIG. 9A is a plan view illustrating the structure at the narrow sheet level for describing a method for forming first inter-cell dielectric layers 21. FIG. 9B is a cross-sectional view of the structure taken along line B-B′ illustrated in FIG. 9A.

As illustrated in FIGS. 9A and 9B, the first inter-cell dielectric layers 21 may be formed in the sacrificial isolation layer-level openings 20. The first inter-cell dielectric layers 21 may each include a dielectric material. The first inter-cell dielectric layers 21 may each include, for example, silicon oxide, silicon nitride, silicon carbon oxide, or a combination thereof. Forming the first inter-cell dielectric layers 21 may include forming a dielectric material that fills the sacrificial isolation layer-level openings 20 and performing an etch-back process on the dielectric material. The etch-back process for forming the first inter-cell dielectric layers 21 may be performed in the second direction D2. Each of the first inter-cell dielectric layers 21 may include a stack of a cell isolation liner and a cell isolation gap-fill layer. The cell isolation liner may be silicon nitride, and a cell isolation gap-fill layer may be silicon oxide or silicon carbon oxide.

The first inter-cell dielectric layers 21 may fill portions of the sacrificial isolation layer-level openings 20. The side surfaces of the first mold layers 12A and the side surfaces of the original body portions 13A may be covered by the first inter-cell dielectric layers 21 in the third direction D3. The first inter-cell dielectric layers 21 may expose the side surfaces of the narrow sheets 13P. The other portions of the sacrificial isolation layer-level openings 20, i.e., non-gap-filled portions of the first inter-cell dielectric layers 21, may expose the side surfaces of the narrow sheets 13P.

From the perspective of a top view, an unfilled space 21R may be defined between the narrow sheets 13P. The unfilled spaces 21R may refer to the other spaces of the sacrificial isolation layer-level openings 20 after the first inter-cell dielectric layers 21 are filled. The first inter-cell dielectric layers 21 may be referred to as “vertical cell isolation layers”or “pillar-shaped cell isolation layers”.

A combination of the unfilled spaces 21R and the inter-nano-sheet recesses 19 may have a surrounding structure of exposing the narrow sheets 13P. Specifically, after the first inter-cell dielectric layers 21 are formed, a nano-sheet all-open recess that opens all of the narrow sheets 13P may be formed. The nano-sheet all-open recess may refer to a combination of inter-nano-sheet recesses 19 and the unfilled spaces 21R. The nano-sheet all-open recess may include a plurality of surrounding recesses. The surrounding recesses may expose all narrow sheets 13P in the third direction D3. For example, any of the surrounding recesses extending in the third direction D3 may surround all surfaces of the narrow sheets 13P at the same horizontal level. Each of the surrounding recesses may include a plurality of initial gaps, and the initial gaps may be defined between the narrow sheets 13P in the third direction D3.

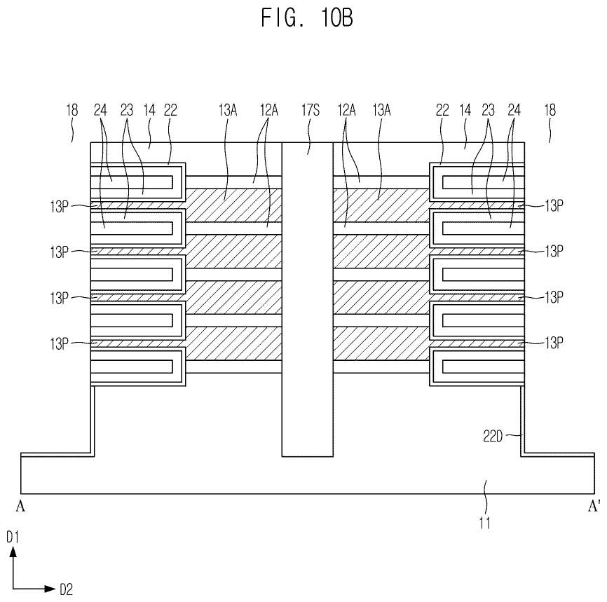

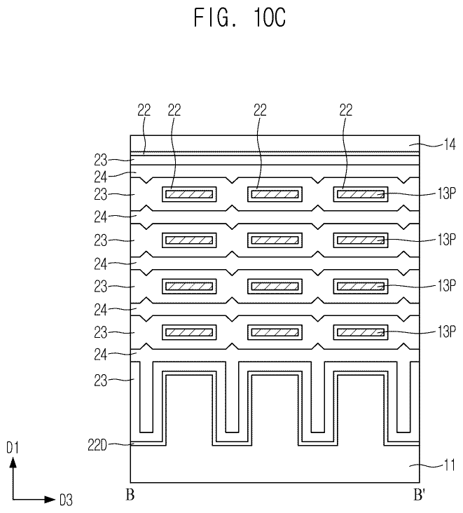

FIG. 10A is a plan view illustrating the structure at the narrow sheet level for describing a method for forming a first spacer layer 23. FIG. 10B is a cross-sectional view of the structure taken along line A-A′ illustrated in FIG. 10A. FIG. 10C is a cross-sectional view of the structure taken along line B-B′ illustrated in FIG. 10A.

As illustrated in FIGS. 10A to 10C, a stack of a nano-sheet dielectric layer 22, the first spacer layer 23 and a second inter-cell dielectric layer 24 may be formed in each of the inter-nano-sheet recesses 19.

The nano-sheet dielectric layer 22 may be formed on an exposed portion of each of the narrow sheets 13P. The nano-sheet dielectric layer 22 may be referred to as a “gate dielectric layer”.

The nano-sheet dielectric layer 22 may be formed by oxidizing the surface of the narrow sheet 13P. In an embodiment, the nano-sheet dielectric layer 22 may be formed by a deposition process of silicon oxide and a surface oxidation process of the narrow sheet 13P. The nano-sheet dielectric layer 22 may include silicon oxide, silicon nitride, metal oxide, metal oxide nitride, metal silicate, a high-k material, a ferroelectric material, an anti-ferroelectric material, or a combination thereof. The nano-sheet dielectric layer 22 may include SiO₂, Si₃N₄, HfO₂, Al₂O₃, ZrO₂, AlON, HfON, HfSiO, HfSiON, or a combination thereof. The nano-sheet dielectric layers 22 may be formed on all surfaces of the narrow sheets 13P. While the nano-sheet dielectric layers 22 are formed, a dummy nano-sheet dielectric layer 22D may be formed on the surface of the substrate 11. The nano-sheet dielectric layer 22 and the dummy nano-sheet dielectric layer 22D may be made of the same material and have an integral structure.

The first spacer layer 23 may be formed on the nano-sheet dielectric layer 22. The first spacer layer 23 may include silicon nitride. The first spacer layer 23 may surround and cover each of the narrow sheets 13P on the nano-sheet dielectric layer 22. The first spacer layer 23 may be thicker than the nano-sheet dielectric layer 22. The first spacer layers 23 may directly contact the first inter-cell dielectric layers 21.

The second inter-cell dielectric layer 24 may be formed on the first spacer layer 23. The second inter-cell dielectric layer 24 may include silicon oxide.

Forming the first spacer layer 23 and the second inter-cell dielectric layer 24 may include conformally forming a first spacer material on the nano-sheet dielectric layer 22, forming a second inter-cell dielectric material on the first spacer material, cutting the second inter-cell dielectric material to form the second inter-cell dielectric layer 24, and cutting the first spacer material to form the first spacer layer 23.

As described above, the first spacer layer 23 may surround each of the narrow sheets 13P in the third direction D3.

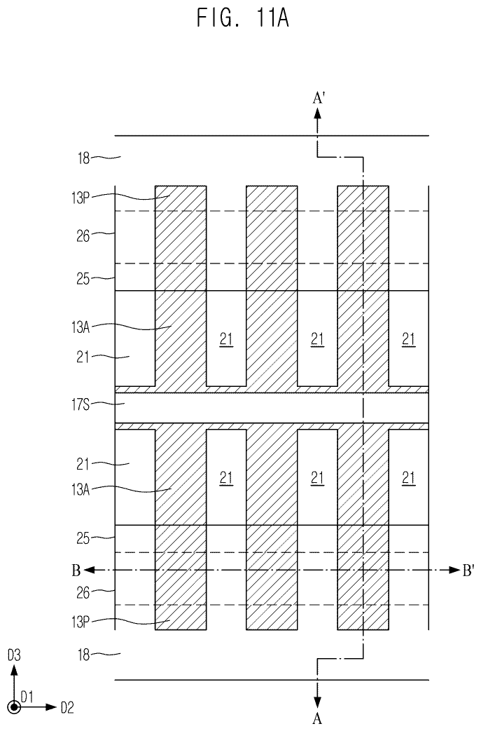

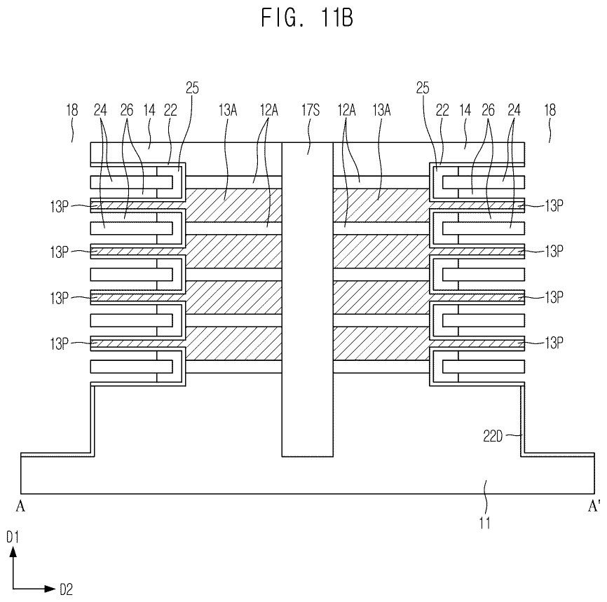

FIG. 11A is a plan view illustrating the structure for describing a method for forming linear surrounding recesses 26. FIG. 11B is a cross-sectional view of the structure taken along line A-A′ illustrated in FIG. 11A. FIG. 11C is a cross-sectional view of the structure taken along line B-B′ illustrated in FIG. 11A.

As illustrated in FIGS. 11A to 11C, the first spacer layer 23 may be selectively recessed through the first linear opening 18. Accordingly, a first spacer 25 may be formed. As the first spacers 25 are formed, the linear surrounding recesses 26 may be formed to surround the narrow sheets 13P on the nano-sheet dielectric layers 22. The second inter-cell dielectric layers 24 may be disposed between the linear surrounding recesses 26 vertically disposed. An upper-level dummy horizontal recess 26U may be formed on an uppermost second inter-cell dielectric layer 24, and a lower-level dummy horizontal recess 26L may be formed below a lowermost second inter-cell dielectric layer 24. The upper-level and lower-level dummy horizontal recesses 26U and 26L, which have non-surrounding shapes, may have flat shapes.

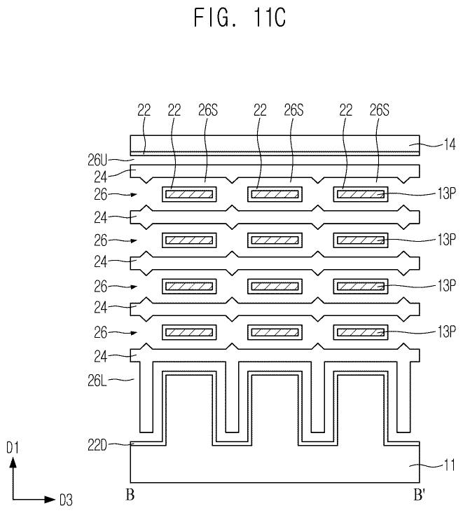

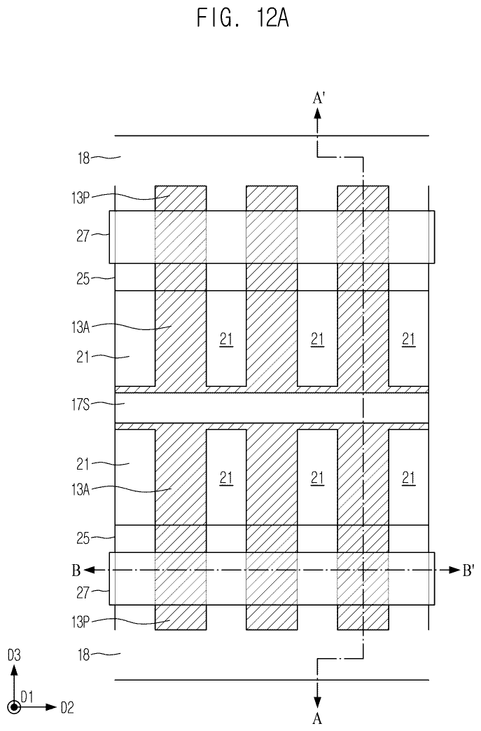

FIG. 12A is a plan view illustrating the structure at the narrow sheet level for describing a method for forming horizontal conductive lines 27. FIG. 12B is a cross-sectional view of the structure taken along line A-A′ illustrated in FIG. 12A. FIG. 12C is a cross-sectional view of the structure taken along line B-B′ illustrated in FIG. 12A.

As illustrated in FIGS. 12A to 12C, the horizontal conductive lines 27 may be formed to fill the linear surrounding recesses 26. The horizontal conductive lines 27 may horizontally extend in the third direction D3. The horizontal conductive lines 27 may correspond to the second conductive lines WL illustrated in FIGS. 2A to 2D.

Forming the horizontal conductive lines 27 may include depositing a conductive material filling the linear surrounding recesses 26 on the nano-sheet dielectric layers 22 and performing a horizontal etch-back process on the conductive material. Each of the horizontal conductive lines 27 may simultaneously surround the narrow sheets 13P at the same horizontal level. The horizontal conductive lines 27 may each include metal, a metal-based material, a semiconductive material, or a combination thereof.

The horizontal conductive lines 27 may each include molybdenum, molybdenum nitride, ruthenium, titanium nitride, tungsten, polysilicon, or a combination thereof. For example, the horizontal conductive lines 27 may each include a TiN/W stack in which titanium nitride and tungsten are sequentially stacked. The horizontal conductive lines 27 may each include an N-type work function material or a P-type work function material. The N-type work function material may have a low work function of approximately 4.5 eV or lower, and the P-type work function material may have a high work function of approximately 4.5 eV or higher. The second inter-cell dielectric layers 24 may be disposed between a plurality of horizontal conductive lines 27 in the first direction D1. The horizontal conductive lines 27 surrounding the narrow sheets 13P may be referred to as “gate-all-around (GAA) electrodes”. The narrow sheets 13P may be referred to as “nano-sheet channels”, “nano wires”, or “nano wire channels”.

A lower-level dummy horizontal electrode 27L may be formed on the surface of the substrate 11. Also, an upper-level dummy horizontal electrode 27U may be formed over an uppermost horizontal conductive line 27. The lower-level and upper-level dummy horizontal electrodes 27L and 27U may each have a non-surrounding shape.

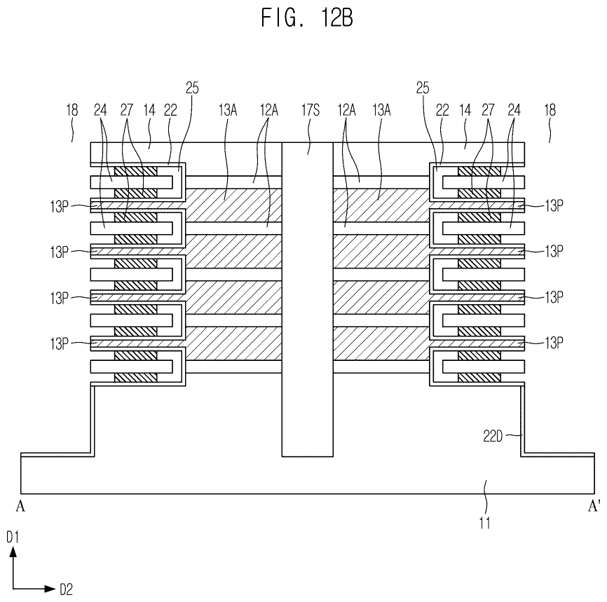

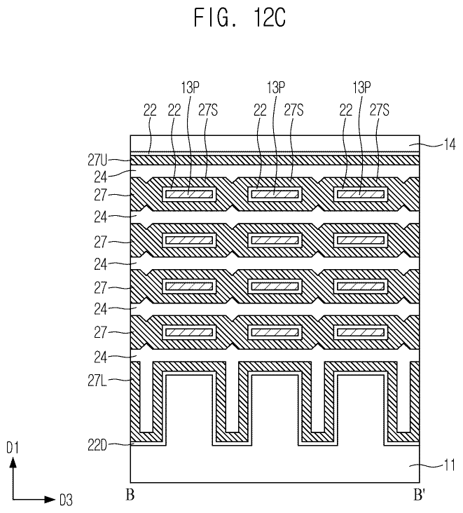

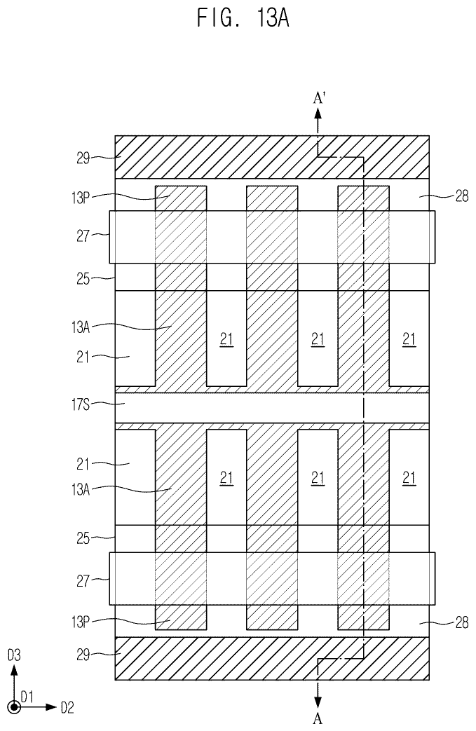

FIG. 13A is a plan view illustrating the structure for describing a method for forming a liner layer 28. FIG. 13B is a cross-sectional view of the structure taken along line A-A′ illustrated in FIG. 13A.

As illustrated in FIGS. 13A and 13B, the liner layer 28 may be formed on one side of each of the horizontal conductive lines 27. The liner layer 28 may include a dielectric material, such as, for example, silicon oxide. The liner layer 28 may be conformally formed on the surfaces of the first linear openings 18.

Sacrificial layers 29 may be formed on the liner layer 28. The sacrificial layers 29 may fill the first linear openings 18 on the liner layer 28. The sacrificial layers 29 may include polysilicon, amorphous carbon, or a combination thereof. The sacrificial layers 29 may have a linear shape extending in the third direction D3.

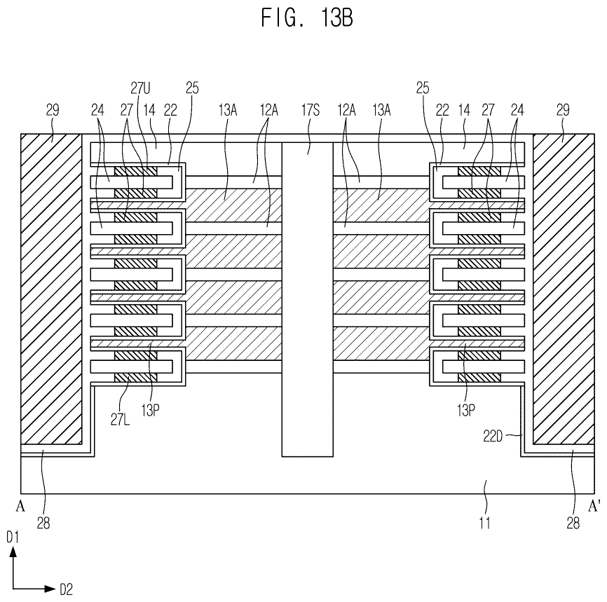

FIG. 14A is a plan view illustrating the structure for describing a method for forming sacrificial patterns 29S. FIG. 14B is a cross-sectional view of the structure taken along line A-A′ illustrated in FIG. 14A.

As illustrated in FIGS. 14A and 14B, a plurality of hole-shaped openings 30 may be formed in the sacrificial layers 29. Portions of the sacrificial layers 29 may be etched to form the hole-shaped openings 30. The hole-shaped openings 30 may extend vertically in the first direction D1. The plurality of hole-shaped openings 30 may be formed in one sacrificial layer 29. The sacrificial layer in which the hole-shaped openings 30 are formed may remain as indicated by reference numeral “29S”. Hereinafter, the remaining sacrificial layer is referred to as a “sacrificial layer pattern 29S”.

The sacrificial layer patterns 29S may be disposed adjacent to the narrow sheets 13P in the second direction D2.

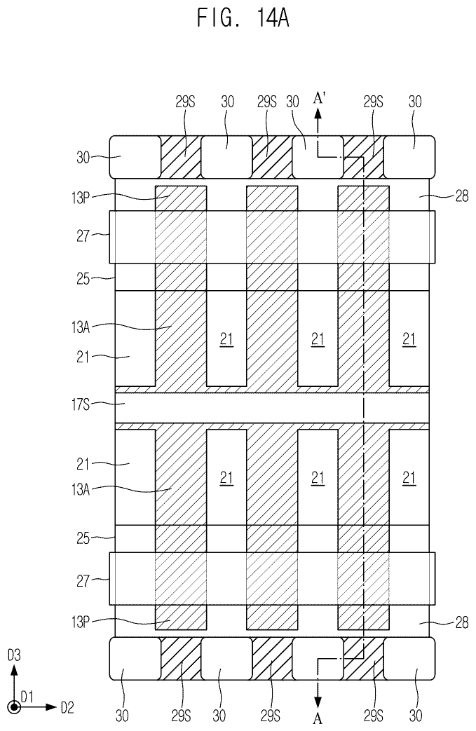

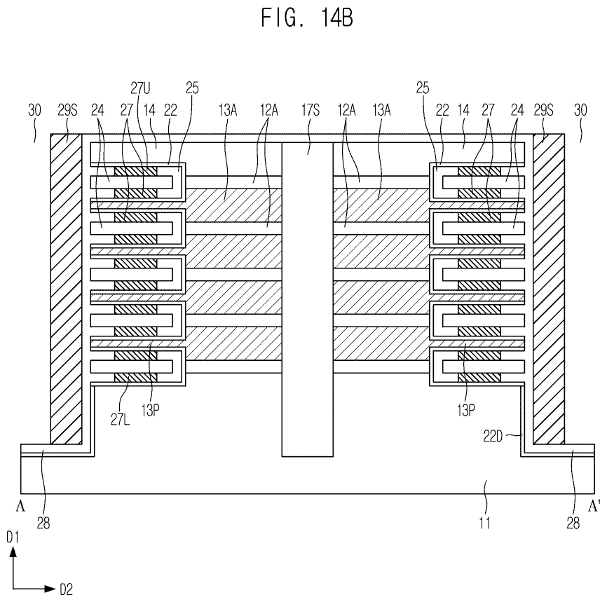

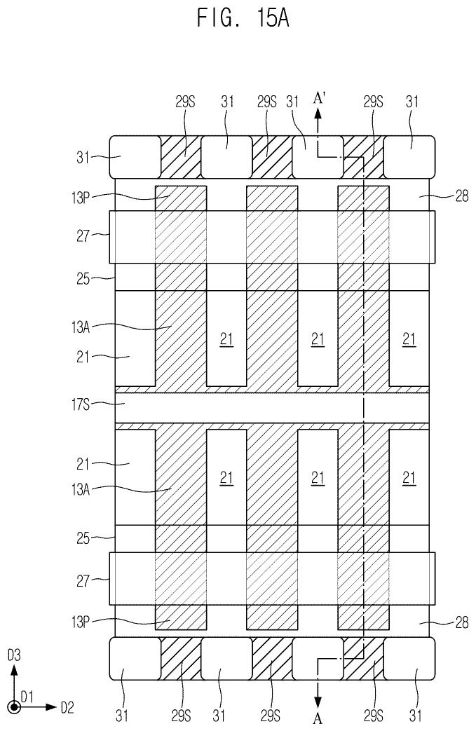

FIG. 15A is a plan view illustrating the structure for describing a method for forming pillar-shaped vertical dielectric layers 31. FIG. 15B is a cross-sectional view of the structure taken along line A-A′ illustrated in FIG. 15A.

As illustrated in FIGS. 15A and 15B, the pillar-shaped vertical dielectric layers 31 may be formed to fill the hole-shaped openings 30. The pillar-shaped vertical dielectric layers 31 may each include dielectric material such as silicon oxide. From the perspective of a top view, the sacrificial layer patterns 29S may be alternately disposed with the pillar-shaped vertical dielectric layers 31 in the third direction D3. The pillar-shaped vertical dielectric layers 31 may contact the liner layer 28. The pillar-shaped vertical dielectric layers 31 may be referred to as “supporters”. The pillar-shaped vertical dielectric layers 31 may correspond to the supporters BLI illustrated in FIGS. 2B to 2E.

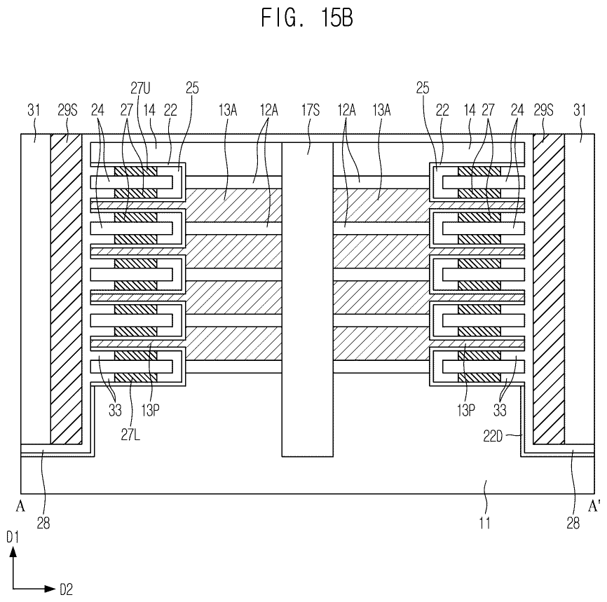

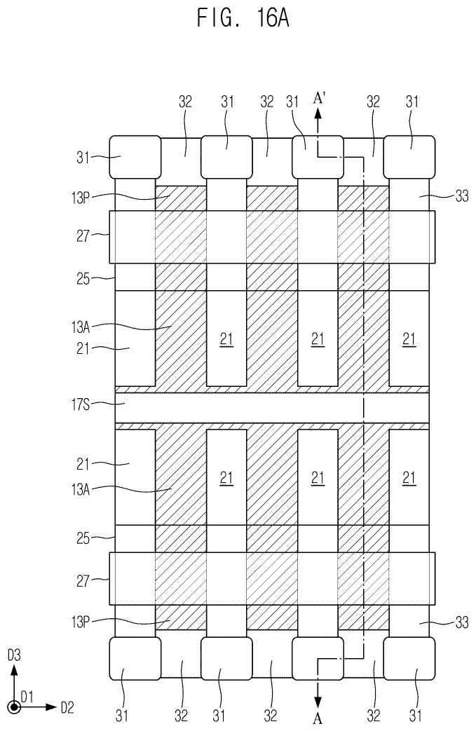

FIG. 16A is a plan view illustrating the structure for describing a method for forming hole-shaped damascene patterns 32. FIG. 16B is a cross-sectional view of the structure taken along line A-A′ illustrated in FIG. 16A.

As illustrated in FIGS. 16A and 16B, the sacrificial layer patterns 29S may be removed, and the hole-shaped damascene patterns 32 may be formed. The hole-shaped damascene patterns 32 may be formed by being self-aligned to the pillar-shaped vertical dielectric layers 31. The pillar-shaped vertical dielectric layers 31 and the hole-shaped damascene patterns 32 may constitute a support structure.

After the hole-shaped damascene patterns 32 are formed, a portion of the liner layer 28 may be removed. The remaining liner layer, i.e., a second spacer 33, may be disposed on side surfaces of the horizontal conductive lines 27. The second spacer 33 may surround the narrow sheets 13P at the same horizontal level. The second spacer 33 may be continuous in the third direction D3. The second spacer 33 may include silicon oxide, silicon nitride, silicon carbon oxide, an embedded air gap, or a combination thereof. The second spacer 33 may include a stack of a silicon oxide liner and a silicon nitride liner.

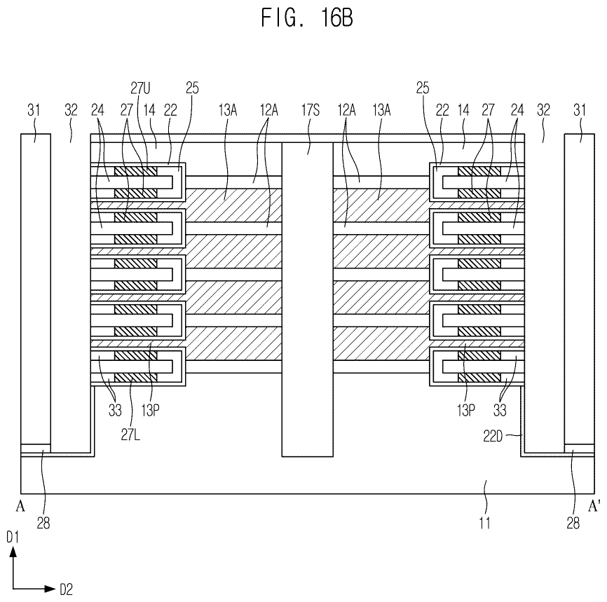

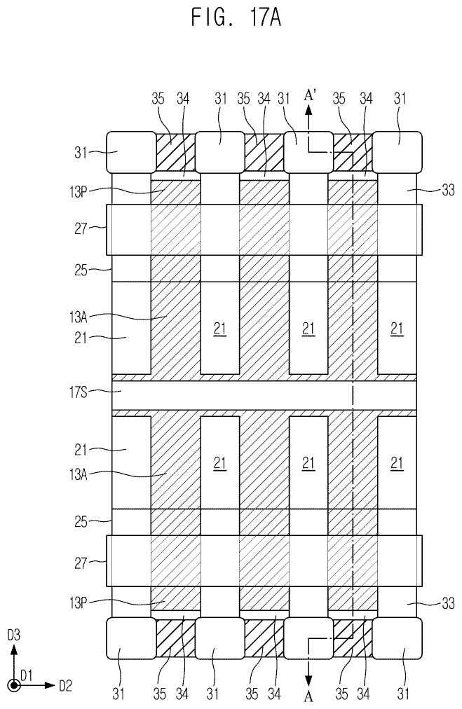

FIG. 17A is a plan view illustrating the structure at the narrow sheet level for describing a method for forming a vertical conductive line 35. FIG. 17B is a cross-sectional view of the structure taken along line A-A′ illustrated in FIG. 17A.

As illustrated in FIGS. 17A and 17B, first contact nodes 34 coupled to the narrow sheets 13P may be formed. The first contact nodes 34 may be formed by selective epitaxial growth. The first contact nodes 34 may include a silicon epitaxial layer or a doped silicon epitaxial layer. In an embodiment, forming the first contact nodes 34 may include depositing a conductive material that fills the hole-shaped damascene patterns 32 and performing an etch-back process on the conductive material. The first contact nodes 34 may include a semiconductive material. The first contact nodes 34 may include doped polysilicon, and the doped polysilicon may include N-type dopants.

In an embodiment, first doped regions may be formed in one side of the narrow sheets 13P. Each of the first doped regions may correspond to the first doped region SR illustrated in FIG. 1B. A heat treatment process may be performed to form the first doped regions, thereby allowing dopants to diffuse from the first contact nodes 34.

A first bottom protective layer 35L may be formed. The first bottom protective layer 35L may include a dielectric material. The first bottom protective layer 35L may include silicon oxide, silicon nitride, silicon carbon oxide, or a combination thereof. In an embodiment, the first bottom protective layer 35L may be formed before the first contact nodes 34 are formed.

The vertical conductive line 35 may be formed on the first contact nodes 34. Before the vertical conductive line 35 is formed, ohmic contact layers may be formed on the first contact nodes 34. The ohmic contact layers may include metal silicide.

The vertical conductive line 35 may fill the hole-shaped damascene pattern 32. The vertical conductive line 35 may be coupled in common to the narrow sheets 13P disposed in the first direction D1. The vertical conductive line 35 may include a metal-based material. The vertical conductive line 35 may include titanium nitride, tungsten, or a combination thereof.

To form the vertical conductive line 35, a deposition process and a planarization process of a conductive material filling the hole-shaped damascene pattern 32 may be performed. The vertical conductive line 35 may be formed in the support structure. That is, the vertical conductive line 35 may be self-aligned to the pillar-shaped vertical dielectric layer 31 to fill each of the hole-shaped damascene patterns 32. The vertical conductive lines 35 disposed adjacent to each other the third direction D3 may be supported by the pillar-shaped vertical dielectric layers 31.

As described above, forming the vertical conductive line 35 may include forming the sacrificial layers 29, forming the hole-shaped openings 30, forming the pillar-shaped vertical dielectric layers 31, forming the hole-shaped damascene patterns 32, and forming a conductive material in the hole-shaped damascene patterns 32. Because the vertical conductive line 35 is formed by a damascene process as described above, process difficulty may be alleviated, and the vertical conductive line 35 may be formed in a self-aligned manner without being affected by an overlay of mask and etch processes.

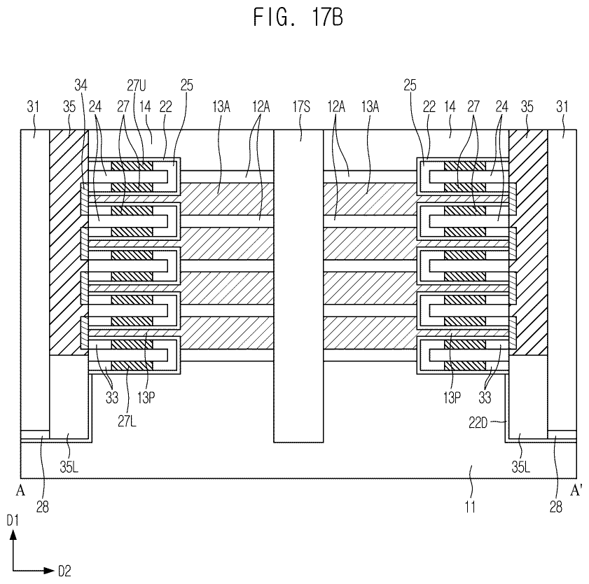

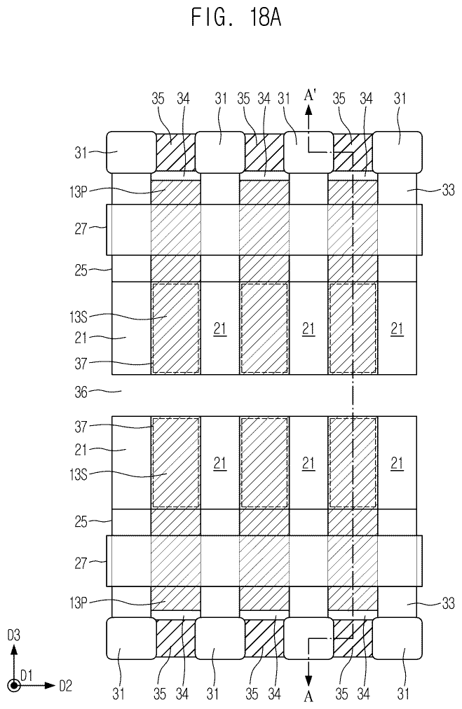

FIG. 18A is a plan view illustrating the structure at a nano-sheet level for describing a method for forming a second linear opening 36. FIG. 18B is a cross-sectional view of the structure taken along line A-A′ illustrated in FIG. 18A.

As illustrated in FIGS. 18A and 18B, the second linear sacrificial layer 17S may be removed, and the second linear opening 36 may be formed. After the second linear opening 36 is formed, the first mold layers 12A may be selectively stripped through the second linear opening 36.

To selectively recess the first mold layers 12A, a difference in etch selectivity between the first mold layers 12A and the original body portions 13A may be used. The first mold layers 12A may be removed using a wet or a dry etch process. For example, when the first mold layers 12A include silicon germanium layers, and the original body portions 13A include monocrystalline silicon layers, the silicon germanium layers may be etched using an etchant or etch gas having a selectivity with respect to the monocrystalline silicon layers.

Subsequently, the original body portions 13A may be recessed. To recess the original body portions 13A, the wet or the dry etch process may be used. Vertical thicknesses of the original body portions 13A may be reduced, as indicated by reference numeral “13S”. Hereinafter, the original body portions having the reduced vertical thicknesses are referred to as “recessed body portions 13S”.

Inter-body recesses 37 may be formed between the recessed body portions 13S that are vertically disposed.

FIG. 19A is a plan view illustrating the structure for describing a method for forming third inter-cell dielectric layers 38. FIG. 19B is a cross-sectional view of the structure taken along line A-A′ illustrated in FIG. 19A.

As illustrated in FIGS. 19A and 19B, the third inter-cell dielectric layers 38 may be formed to fill the inter-body recesses 37. The third inter-cell dielectric layers 38 may each include, for example, silicon oxide.

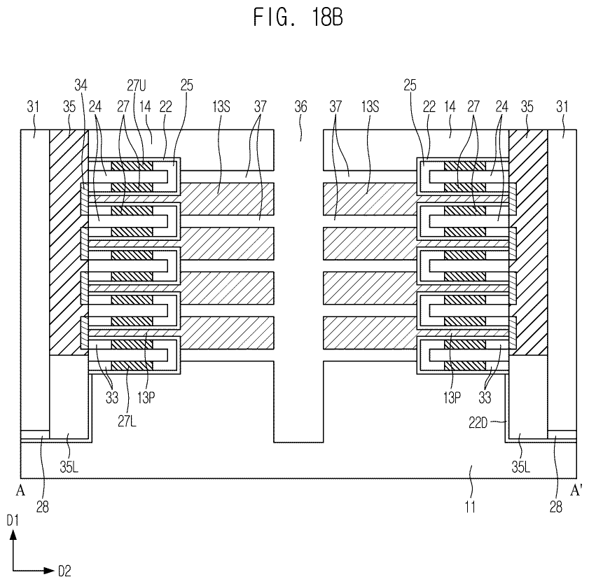

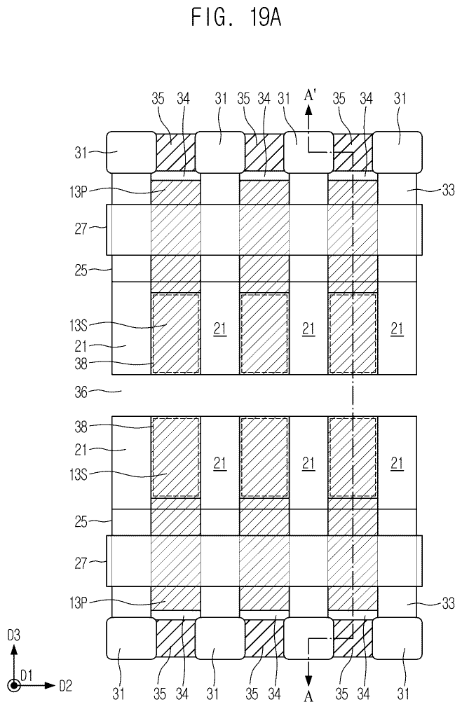

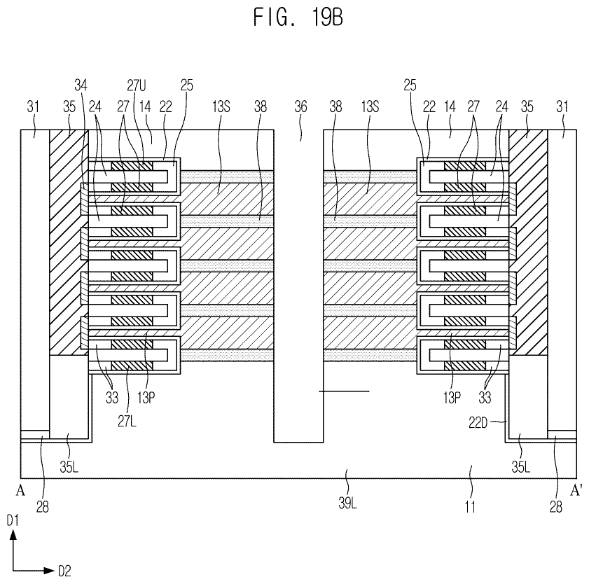

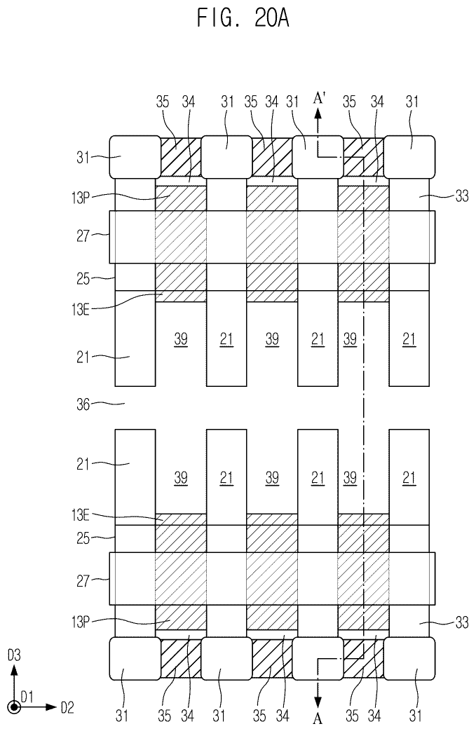

FIG. 20A is a plan view illustrating the structure at the narrow sheet level for describing a method for forming nano-sheets HL. FIG. 20B is a cross-sectional view of the structure taken along line A-A′ illustrated in FIG. 20A.

As illustrated in FIGS. 20A and 20B, a second bottom protective layer 39L may be formed at a bottom portion of the second linear opening 36. The second bottom protective layer 39L may include a material having an etch selectivity with respect to the substrate 11. The second bottom protective layer 39L may include a dielectric material. The second bottom protective layer 39L may include silicon oxide, silicon nitride, silicon carbon oxide, or a combination thereof.

Storage openings 39 may be formed by horizontal recessing of the recessed body portions 13S. The storage openings 39 may be referred to as “data storage element openings”. The nano-sheets HL may be formed by the horizontal recessing of the recessed body portions 13S. Each of the nano-sheets HL may include the narrow sheet 13P and a wide sheet 13E. The wide sheet 13E of the nano-sheet HL may refer to the recessed body portion 13S remaining after the recessing. An average vertical height of the wide sheets 13E of the nano-sheets HL in the first direction D1 may be greater than an average vertical height of the narrow sheets 13P. Thicknesses of the wide sheets 13E of the nano-sheets HL may gradually increase in the second direction D2. Horizontal lengths of the wide sheets 13E in the second direction D2 may be less than horizontal lengths of the narrow sheets 13P. The wide sheets 13E of the nano-sheets HL may each have a fan-like shape. The wide sheets 13E may be referred to as “fan-shaped sheets”, and the narrow sheets 13P may be referred to as “flat plate-shaped sheets”. The wide sheets 13E may each extend in the first direction D1 between adjacent third inter-cell dielectric layers 38 as illustrated in FIG. 20B.

The recessing process of the recessed body portions 13S to form the wide sheets 13E and the storage openings 39 may include an isotropic etch process or an anisotropic etch process. During the recessing process of the recessed body portions 13S, loss of the substrate 11 may be prevented by the second bottom protective layer 39L. One side of each of the wide sheets 13E, i.e., the side exposed by each of the storage openings 39, may have a flat shape. In an embodiment, one side of the wide sheet 13E may have various shapes. For example, the one side of the wide sheet 13E may have a rounded concave shape, a rounded convex shape, an angled concave shape, or an angled convex shape.

Each of the nano-sheets HL may include a first edge and a second edge. The first edge may be coupled to the vertical conductive line 35, and the second edge opposite to the first edge in the second direction D2 may be exposed to a corresponding one of the storage openings 39.

Each of the storage openings 39 may be disposed between a pair of adjacent third inter-cell dielectric layers 38.

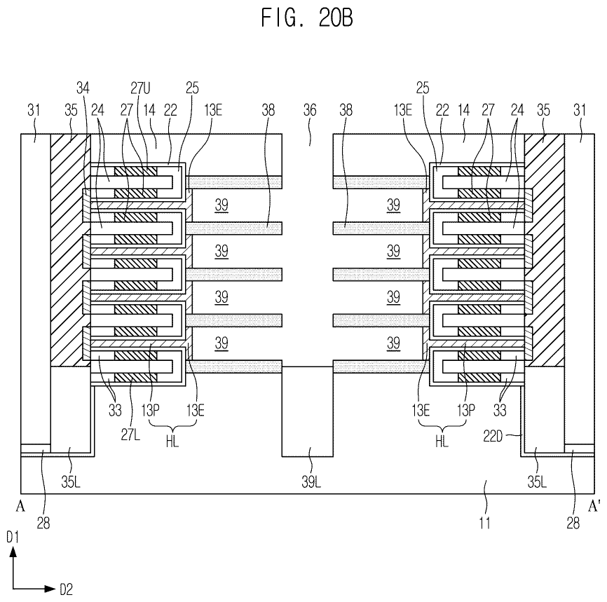

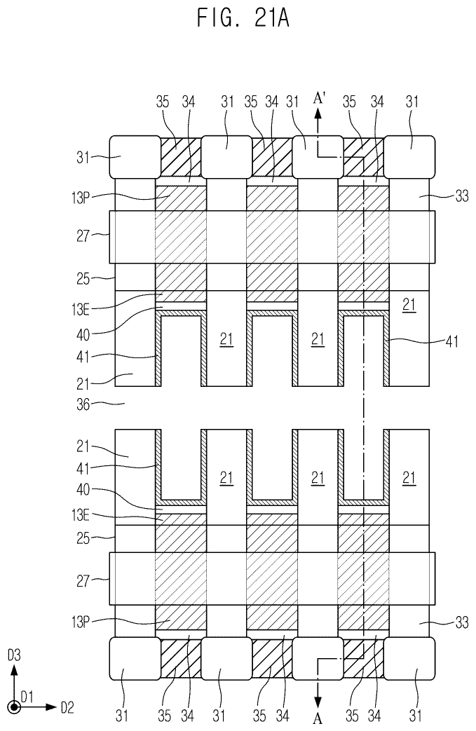

FIG. 21A is a plan view illustrating the structure at the nano-sheet level for describing a method for forming second contact nodes 40 and first electrodes 41. FIG. 21B is a cross-sectional view of the structure taken along line A-A′ illustrated in FIG. 21A.

As illustrated in FIGS. 21A and 21B, a pre-cleaning process may be performed on one side of each of the nano-sheets HL, that is, the surfaces of the wide sheets 13E.

Each of the second contact nodes 40 may be formed on a different one of the wide sheets 13E of the nano-sheets HL. Forming the second contact nodes 40 may include conformally depositing a conductive material on the storage openings 39 and performing an etch-back operation on the conductive material. The second contact nodes 40 may each include a semiconductive material. The second contact nodes 40 may be formed by the deposition and etch-back processes of doped polysilicon. The second contact nodes 40 may each include doped polysilicon, and the doped polysilicon may include N-type dopants. The second contact nodes 40 may be disposed between the third inter-cell dielectric layers 38 vertically stacked.

In an embodiment, forming the second contact nodes 40 may include selective epitaxial growth (SEG). For example, a semiconductive material may be grown from the side surfaces of the wide sheets 13E through the selective epitaxial growth (SEG). The second contact nodes 40 may each include SEG Si. Since the wide sheets 13E each include monocrystalline silicon, a silicon layer may be epitaxially grown along crystal surfaces of the side surfaces of the wide sheets 13E. The second contact nodes 40 may each include a dopant. When the silicon layer is grown using the selective epitaxial growth (SEG), dopants may be doped in situ. Accordingly, the second contact nodes 40 may each be a doped epitaxial layer. The second contact nodes 40 may each include an N-type dopant as the dopant. The N-type dopant may include phosphorus, arsenic, antimony, or a combination thereof. The second contact nodes 40 may include a phosphorus-doped silicon epitaxial layer formed by the selective epitaxial growth (SEG), i.e., a doped SEG SiP. In an embodiment, the first contact nodes may also be formed through the selective epitaxial growth (SEG).

One side of each of the second contact nodes 40 may have various shapes. For example, one side of each of the second contact nodes 40 may have a rounded concave shape, a rounded convex shape, an angled concave shape, or an angled convex shape.

In an embodiment, second doped regions (refer to reference symbol “DR” of FIG. 1B) may be formed in the wide sheets 13E of the nano-sheets HL. A heat treatment process may be performed to form the second doped regions, thereby allowing dopants to diffuse from the second contact nodes 40 to the wide sheets 13E.

In an embodiment, an ohmic contact layer including metal silicide may be further formed after the second contact nodes 40 are formed.

Subsequently, the first electrodes 41 of the data storage elements may be formed on the second contact nodes 40. The first electrodes 41 may each have a horizontally oriented cylindrical shape. The first electrodes 41 may be respectively disposed in the storage openings 39. The first electrodes 41 disposed adjacent to each other in the second direction D2 may be spaced apart from each other by the second linear openings 36. The first electrodes 41 disposed adjacent to each other in the third direction D3 may be spaced apart from each other by the first inter-cell dielectric layers 21. The first electrodes 41 disposed adjacent to each other in the first direction D1 may be spaced apart from each other by the third inter-cell dielectric layers 38. Forming the first electrodes 41 may include depositing a metal material, gap-filling a sacrificial material, and isolating the metal material in vertical and horizontal directions. The sacrificial material may include oxide or polysilicon.

Each of the first electrodes 41 may include an inner space and a plurality of outer surfaces, and the inner space of the first electrode 41 may include a plurality of inner surfaces. The outer surfaces of the first electrode 41 may include a vertical outer surface and a plurality of horizontal outer surfaces. The vertical outer surface of the first electrode 41 may extend vertically in the first direction D1, and the horizontal outer surfaces of the first electrode 41 may horizontally extend in the second direction D2 or the third direction D3. The inner space of the first electrode 41 may be a three-dimensional space.

Among the outer surfaces of the first electrode 41, the vertical outer surface may be electrically coupled to the nano-sheet HL and the second contact node.

The first electrode 41 may include metal, noble metal, metal nitride, conductive metal oxide, conductive noble metal oxide, metal carbide, metal silicide, or a combination thereof. For example, the first electrode 41 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

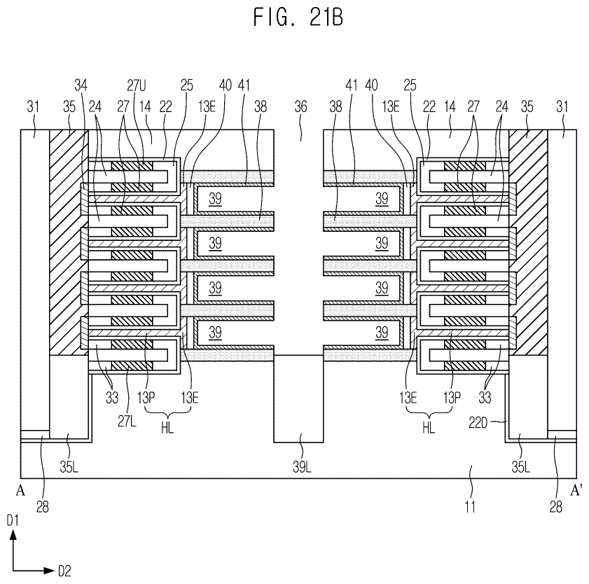

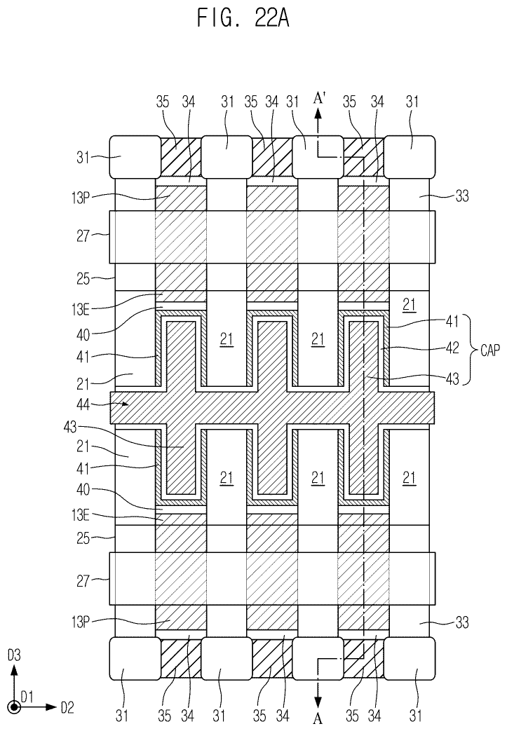

FIG. 22A is a plan view illustrating the structure at the nano-sheet level for describing a method for forming second electrodes 43 of the data storage elements. FIG. 22B is a cross-sectional view of the structure taken along line A-A′ illustrated in FIG. 22A.

As illustrated in FIGS. 22A and 22B, a dielectric layer 42 and the second electrode 43 may be sequentially formed on each of the first electrodes 41. The first electrode 41, the dielectric layer 42 and the second electrode 43 form the data storage element CAP. The second electrodes 43 of the data storage elements CAP may be merged with each other and become a common plate 44.

The dielectric layer 42 may conformally cover the inner surfaces of the first electrode 41. The second electrode 43 may be disposed on the inner spaces of the first electrode 41 on the dielectric layer 42.

In an embodiment, the first electrode 41 may have a semi-cylindrical shape. The semi-cylindrical shape of the first electrode 41 may include cylindrical inner surfaces and semi-cylindrical outer surfaces. The third inter-cell dielectric layers 38 may be horizontally recessed to form the first electrodes 41 each having the semi-cylindrical shape, and the dielectric layers 42 and the second electrodes 43 may be formed after the recessing of the third inter-cell dielectric layers 38. Each of the dielectric layers 42 and each of the second electrodes 43 may be disposed on the cylindrical inner surfaces of the first electrode 41. A portion of the dielectric layer 42 and a portion of the second electrode 43 may extend to be disposed on the semi-cylindrical outer surfaces of the first electrode 41. The second electrode 43 may extend vertically in the first direction D1.

The dielectric layer 42 may be referred to as a “capacitor dielectric layer” or a “memory layer”. The dielectric layer 42 may include silicon oxide, silicon nitride, a high-k material, a ferroelectric material, an antiferroelectric material, a perovskite material, or a combination thereof. The dielectric layer 42 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 42 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

The second electrode 43 may include metal, noble metal, metal nitride, conductive metal oxide, conductive noble metal oxide, metal carbide, metal silicide, or a combination thereof. For example, the second electrode 43 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 43 may also include a combination of a metal-based material and a silicon-based material. For example, titanium nitride, tungsten and polysilicon may be sequentially stacked in the second electrode 43.

In an embodiment, an interface control layer may be further formed between the first electrode 41 and the dielectric layer 42 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 43 and the dielectric layer 42.

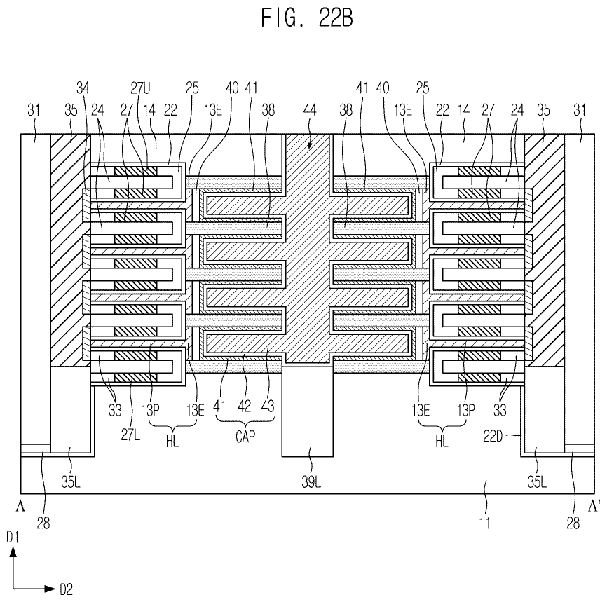

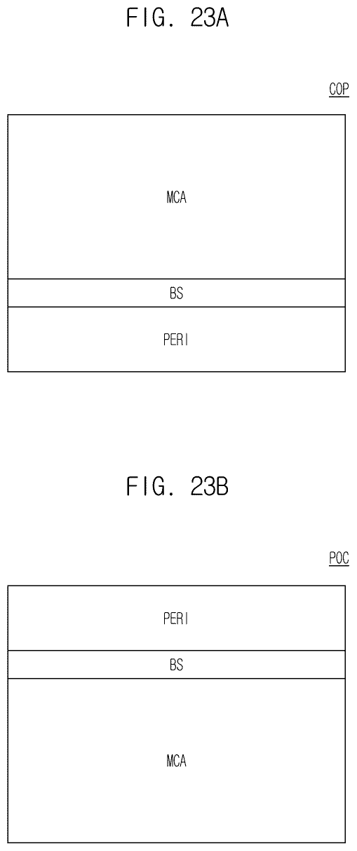

FIGS. 23A and 23B are schematic cross-sectional views of a semiconductor device in accordance with an embodiment of the present disclosure.

As illustrated in FIG. 23A, a semiconductor device COP may include a memory cell array MCA, a peripheral circuit portion PERI, and a bonding interface BS disposed between the memory cell array MCA and the peripheral circuit portion PERI. In the semiconductor device COP, the memory cell array MCA may be disposed at a higher level than the peripheral circuit portion PERI. The semiconductor device COP may be referred to as a “Peri Under Cell array (PUC) structure”. The memory cell array MCA may include a substrate on which back grinding is performed and an array of memory cells. For example, as described with reference to FIG. 22B, after the data storage element CAP is formed, the substrate 11 may be flipped over through a wafer flip, and then the substrate 11 may be partially ground back.

As illustrated in FIG. 23B, a semiconductor device POC may include a memory cell array MCA, a peripheral circuit portion PERI, and a bonding interface BS disposed between the memory cell array MCA and the peripheral circuit portion PERI. In the semiconductor device POC, the memory cell array MCA may be disposed at a lower level than the peripheral circuit portion PERI. The semiconductor device POC may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 23A and FIG. 23B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 23A may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 23B may perform the wafer flip on the substrate on which the peripheral circuit portion is formed so that the cell bonding pad and the peripheral circuit bonding pad face each other, after the cell bonding pad and the peripheral circuit bonding pad are formed.

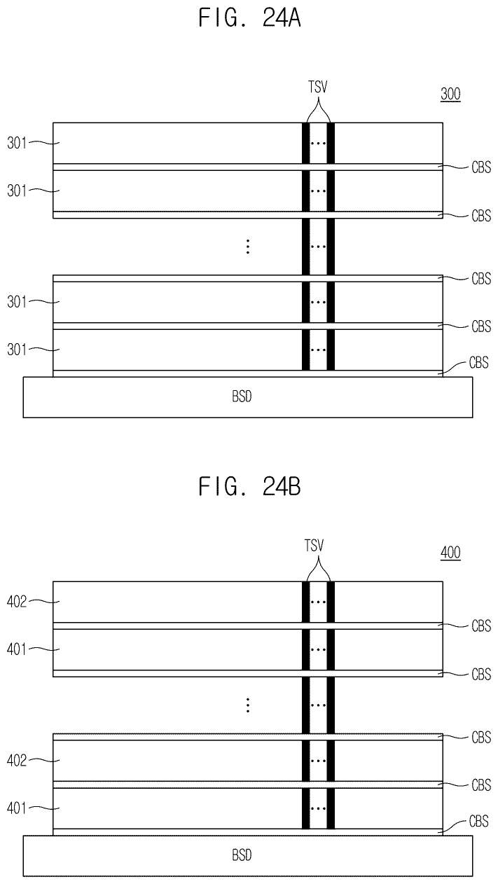

FIGS. 24A and 24B illustrate various views illustrating a stack assembly in accordance with an embodiment of the present disclosure.

As illustrated in FIG. 24A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to embodiments described above. Each of the second semiconductor dies 301 may include structures in which a memory cell array and a peripheral circuit portion are stacked, for example, the semiconductor device COP illustrated in FIG. 23A or the semiconductor device POC illustrated in FIG. 23B. The logic circuits of the first semiconductor die BSD may be different from the peripheral circuit portions of the second semiconductor dies 301. The second semiconductor dies 301 may have chip levels or wafer levels.

The second semiconductor dies 301 may be electrically coupled to each other through a plurality of through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, the second semiconductor dies 301 may be wafer-flipped and ground back to form the bonding interfaces CBS.

As illustrated in FIG. 24B, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second and third semiconductor dies 401 and 402 may include memory cell arrays according to embodiments described above. The second and third semiconductor dies 401 and 402 may have different structures.

Each of the second semiconductor dies 401 may include the semiconductor device COP illustrated in FIG. 23A in which a memory cell array is stacked over a peripheral circuit portion. Each of the third semiconductor dies 402 may include the semiconductor device POC illustrated in FIG. 23B in which a peripheral circuit portion is stacked over a memory cell array.

In an embodiment, each of the second semiconductor dies 401 may include the semiconductor device POC illustrated in FIG. 23B in which a peripheral circuit portion is stacked over a memory cell array, and each of the third semiconductor dies 402 may include the semiconductor device COP illustrated in FIG. 23A in which a memory cell array is stacked over a peripheral circuit portion.

The logic circuits of the first semiconductor die BSD may be different from the peripheral circuit portions of the second and third semiconductor dies 401 and 402. The second and third semiconductor dies 401 and 402 may have chip levels or wafer levels.

The second and third semiconductor dies 401 and 402 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, wafer-flip and back grinding may be performed to form the bonding interface CBS. For example, the second semiconductor dies 401 and/or the third semiconductor dies 402 may be wafer-flipped and ground back.

The stack assemblies 300 and 400 illustrated in FIGS. 24A and 24B may be high bandwidth memories.

According to various embodiments of the present disclosure, it is possible to increase structural stability of 3D memory cells because vertical conductive lines are supported by supporters.

According to various embodiments of the present disclosure, it is possible to alleviate process difficulty because vertical conductive lines are formed by a damascene process and to form the vertical conductive lines to be self-aligned without being affected by an overlay of mask and etch processes.

While the embodiments of the present disclosure have been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the technical concepts and/or the scope of the present disclosure and the following claims. Furthermore, the embodiments may be combined to form additional embodiments.

What is claimed is:

1. A method for fabricating a semiconductor device, the method comprising:
forming a mold stack including a plurality of mold layers that are vertically stacked over a substrate;
forming a sacrificial layer in the mold stack;
etching the sacrificial layer and forming a plurality of sacrificial layer patterns and a plurality of hole-shaped openings;
forming pillar-shaped vertical dielectric layers filling the hole-shaped openings;
removing the sacrificial layer patterns and forming damascene patterns self-aligned to the pillar-shaped vertical dielectric layers; and
forming a vertical conductive line filling the damascene patterns.

2. The method of claim 1, wherein forming the sacrificial layer includes:
etching the mold stack and forming a linear opening that is horizontally oriented; and
forming a sacrificial material filling the linear opening.

3. The method of claim 1, wherein the sacrificial layer includes a material having an etch selectivity with respect to the mold stack.

4. The method of claim 1, wherein the sacrificial layer includes polysilicon, amorphous carbon, or a combination thereof.

5. The method of claim 1, wherein in the mold stack, first semiconductor layers that are epitaxially grown are alternately stacked with second semiconductor layers that are epitaxially grown.

6. The method of claim 1, wherein the plurality of sacrificial layer patterns and the plurality of hole-shaped openings are disposed horizontally and alternately.

7. The method of claim 1, further comprising selectively growing first contact nodes from edges of the mold layers of the mold stack, before forming the vertical conductive line.

8. A method for fabricating a semiconductor device, the method comprising:
forming a column array and a row array of nano-sheets;
forming a horizontal conductive line surrounding the nano-sheets with the row array;
forming a sacrificial layer coupled to the nano-sheets with the column array and extending along the row array;
etching the sacrificial layer and forming a plurality of sacrificial layer patterns and a plurality of hole-shaped openings that extend vertically along the column array and alternate with each other along the row array;
forming pillar-shaped vertical dielectric layers filling the hole-shaped openings;
removing the sacrificial layer patterns and forming damascene patterns exposing in common the nano-sheets with the column array and spaced apart from each other along the row array; and
forming vertical conductive lines filling the damascene patterns, coupled in common the nano-sheets with the column array and spaced apart from each other along the row array.

9. The method of claim 8, wherein forming the sacrificial layer includes:
forming a linear opening exposing in common the nano-sheets with the column array and extending along the row array; and
forming a sacrificial material filling the linear opening.

10. The method of claim 9, wherein the sacrificial layer includes polysilicon, amorphous carbon, or a combination thereof.

11. The method of claim 8, wherein the nano-sheets include semiconductor layers that are epitaxially grown.

12. The method of claim 8, wherein forming the column array and the row array of the nano-sheets includes:
forming a mold stack in which first semiconductor layers epitaxially grown are alternately stacked with second semiconductor layers epitaxially grown, over a substrate;
stripping the second semiconductor layers; and
recessing the first semiconductor layers to form the column array and the row array of the nano-sheets.

13. The method of claim 12, wherein the first semiconductor layers include silicon layers that are epitaxially grown, and the second semiconductor layers include silicon germanium layers that are epitaxially grown.

14. The method of claim 8, further comprising selectively growing first contact nodes from first edges of the nano-sheets, before forming the vertical conductive lines.

15. The method of claim 14, wherein the first contact nodes are formed by selective epitaxial growth of a silicon layer.

16. The method of claim 8, further comprising:
after forming the vertical conductive lines,
forming second contact nodes on second edges of the nano-sheets, respectively; and
forming data storage elements coupled to the second contact nodes, respectively.

17. The method of claim 16, wherein the second contact nodes are formed by deposition and etch processes of polysilicon.

18. A semiconductor device comprising:
a column array and a row array of nano-sheets;
horizontal conductive lines surrounding in common the nano-sheets with the row array and respectively surrounding the nano-sheets with the column array;
data storage elements respectively coupled to the nano-sheets with the column array and the row array;
a supporter including damascene patterns exposing in common the nano-sheets with the column array and respectively exposing the nano-sheets with the row array; and
vertical conductive lines respectively filling the damascene patterns of the supporter, coupled in common to the nano-sheets with the column array, and respectively coupled to the nano-sheets with the row array.

19. The semiconductor device of claim 18, wherein the supporter includes silicon oxide.

20. The semiconductor device of claim 18, further comprising:
first contact nodes disposed between the vertical conductive lines and the nano-sheets; and
second contact nodes disposed between the data storage elements and the nano-sheets.
